(19) United States
(12) Patent Application Publication
(10) Pub. No.: US 2026/0214975 A1
(43) Pub. Date: Jul. 23, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ching-Han MAO, Hsinchu City (TW); Chih-Yi CHANG, New Taipei City (TW); Jau-Jiun HUANG, Kaohsiung City (TW); Chien-Hsueh SHIH, New Taipei City (TW); Chun-Chieh LIN, Taichung City (TW)

(21) Appl. No.: 19/196,343

(22) Filed: May 1, 2025

Related U.S. Application Data
(60) Provisional application No. 63/748,766, filed on Jan. 23, 2025.

(51) Int. Cl. H10D 84/83; H01L 21/285; H01L 21/288; H01L 21/768; H01L 23/522; H01L 23/528; H10D 30/00; H10D 30/01; H10D 30/43; H10D 62/10; H10D 62/13; H10D 84/01

(52) U.S. Cl. CPC H10D 84/832; H10D 30/014; H10D 30/0191; H10D 30/43; H10D 30/502; H10D 62/121; H10D 62/151; H10D 84/0149; H10P 14/43; H10P 14/46; H10W 20/038; H10W 20/063; H10W 20/42; H10W 20/435

(57) ABSTRACT

A layer of conductive material is formed above a bottom-most layer of interconnect structures in an interconnect layer of a semiconductor device, and the layer of conductive material is etched to define the bottom-most layer of metallization structures from the layer of conductive material. To reduce contact resistance between the bottom-most layer of interconnect structures and the bottom-most layer of metallization structures in the interconnect layer, an adhesion layer may be formed in a selective manner so that the adhesion layer is formed only on an underlying dielectric layer and not on the bottom-most layer of interconnect structures.

Selective deposition of the adhesion layer may be achieved using a blocking layer that is selectively formed on the bottom-most layer of interconnect structures.

### CROSS-REFERENCE TO RELATED APPLICATION

This Patent Application claims priority to U.S. Provisional Patent Application No. 63/748,766, filed on Jan. 23, 2025, and entitled “SEMICONDUCTOR DEVICE AND METHODS OF FORMATION.” The disclosure of the prior Application is considered part of and is incorporated by reference into this Patent Application.

### BACKGROUND

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2D are diagrams of an example implementation of forming a device layer (or a portion thereof) a semiconductor device described herein.

FIGS. 3A-3O are diagrams of an example implementation of forming an interconnect layer (or a portion thereof) of a semiconductor device described herein.

FIG. 4 is a flowchart of an example process associated with forming a semiconductor device described herein.

FIG. 5 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer of a semiconductor device may be formed above a device layer of the semiconductor device. The device layer may include a substrate layer of the semiconductor device and integrated circuit devices (e.g., transistors, capacitors, diodes, memory cells) in and/or on the semiconductor substrate. A layer of contact structures (e.g., source/drain contacts, gate contacts) may be included in the device layer, and a bottom-most layer of interconnect structures (e.g., source/drain interconnect structures, gate interconnect structures, sometimes referred to as a via-0 or V0 layer) may be located at the bottom of the interconnect layer between the contact structures and higher layers in the interconnect layer. The contact structures and the bottom-most layer of interconnect structures may electrically connect the integrated circuit devices and the higher layers of conductive structures in the interconnect layer.

A bottom-most layer of metallization structures (sometimes referred to as a metal-0 or M0 layer) in the interconnect layer may be included above the bottom-most layer of interconnect structures. The bottom-most layer of metallization structures may be formed by forming recesses in a dielectric layer above the bottom-most layer of interconnect structures such that the top surfaces of the bottom-most layer of interconnect structures are exposed through the recesses, and depositing the material of the bottom-most layer of metallization structures in the recesses such that the bottom-most layer of metallization structures are electrically coupled to the bottom-most layer of interconnect structures.

However, as the size of integrated circuit devices is reduced, the size and spacing between metallization structures in the interconnect layer is also reduced. Thus, the size and spacing between metallization structures in the bottom-most layer of metallization structures is reduced, which may result in reduced gap-filling performance for the bottom-most layer of metallization structures. This may result in the occurrence of voids and/or other discontinuities in the bottom-most layer of metallization structures, which may increase the contact resistance of the bottom-most layer of metallization structures and/or may result in electrical disconnects between the bottom-most layer of metallization structures and the bottom-most layer of interconnect structures. The gap-filling performance may be worsened by the inclusion of liners in the recesses that protect against material migration from the bottom-most layer of metallization structures and/or provide for enhanced adhesion between the bottom-most layer of metallization structures and the dielectric layer.

In some implementations described herein, a layer of conductive material is formed above a bottom-most layer of interconnect structures in an interconnect layer of a semiconductor device, and the layer of conductive material is etched to define the bottom-most layer of metallization structures from the layer of conductive material, as opposed to forming the bottom-most layer of metallization structures in recesses in a dielectric layer. An adhesion layer may first be deposited, and the layer of conductive material may be deposited on the adhesion layer so that the adhesion layer reduces the likelihood of collapse of the bottom-most layer of metallization structures. The areas between the free-standing metallization structures may then be sealed with a low dielectric constant (low-k) dielectric plug so that airgaps remain between the metallization structures as low-k electrical isolation. The airgaps enable the bottom-most layer of metallization structures to be electrically isolated without the use of liners, which provides for a greater area for the bottom-most layer of metallization structures and a lower contact resistance.

To further reduce contact resistance between the bottom-most layer of interconnect structures and the bottom-most layer of metallization structures in the interconnect layer, the adhesion layer may be formed in a selective manner so that the adhesion layer is formed only on an underlying dielectric layer and not on the bottom-most layer of interconnect structures. In this way, the bottom-most layer of metallization structures may be formed directly on the bottom-most layer of interconnect structures (as opposed to the adhesion layer being between the bottom-most layer of interconnect structures and the bottom-most layer of metallization structures), which reduces the contact resistance between the bottom-most layer of interconnect structures and the bottom-most layer of metallization structures.

To achieve the selective deposition of the adhesion layer, a blocking layer may be selectively formed on the bottom-most layer of interconnect structures. The blocking layer may include a self-assembled monolayer that selectively grows on the bottom-most layer of interconnect structures and not on the underlying dielectric layer in which the bottom-most layer of interconnect structures were formed. The selective growth of the self-assembled monolayer on the bottom-most layer of interconnect structures and not on the underlying dielectric layer inhibits deposition of the adhesion layer on the bottom-most layer of interconnect structures while still enabling the adhesion layer to be deposited on the underlying dielectric layer. In this way, the self-assembled monolayer enables a low contact resistance to be achieved, with minimal impact to the structural integrity of the bottom-most layer of metallization structures.

Additionally and/or alternatively, the adhesion layer may be formed using a deposition technique such as atomic layer deposition (ALD) to achieve an amorphous structure for the material of the adhesion layer. The amorphous structure of the adhesion layer promotes the formation of a larger grain size in the metal layer, and the larger grain size of the metal layer may reduce line resistance in the bottom-most layer of conductive structures.

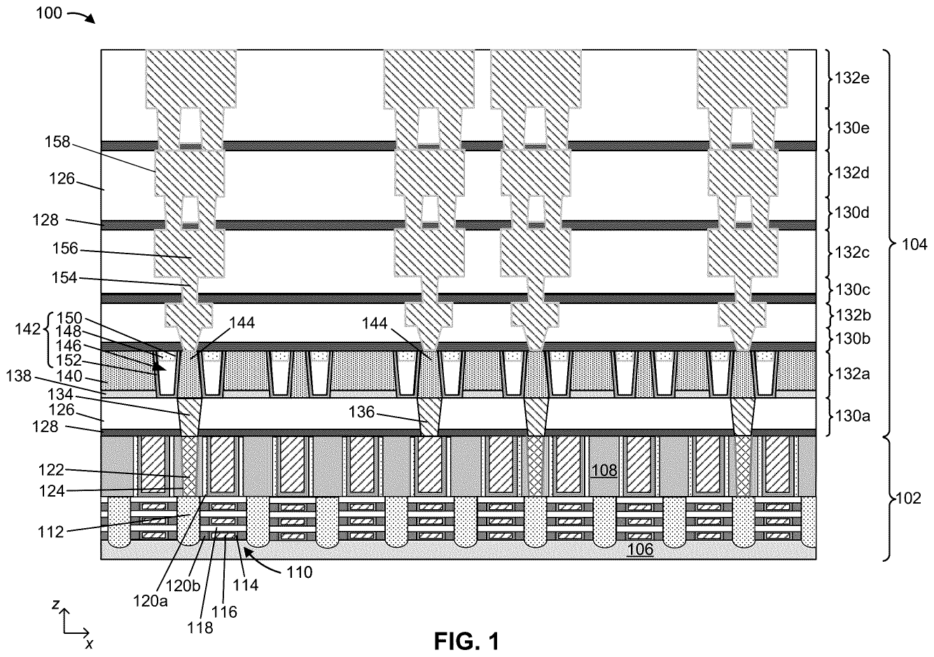

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), a display device (e.g., an organic light emitting diode (OLED) display device), and/or another type of semiconductor device.

As shown in FIG. 1, the semiconductor device 100 may include a device layer 102 and an interconnect layer 104 arranged in a z-direction in the semiconductor device 100 with the device layer 102. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe) layers).

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal). In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer includes another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114. In some implementations, the sidewall spacers 120a are in contact with the work function metal layer. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 120b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The source/drain regions 112 are electrically coupled and/or physically coupled with source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the substrate layer 106 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 includes a plurality of backend conductive structures that are arranged in a plurality of layers. The backend conductive structures may be electrically coupled and/or physically coupled to one or more of the integrated circuit devices 110 in the device layer 102. The backend conductive structures provide electrical routing that enables signals and/or power to be provided to and/or from the integrated circuit devices 110.

The layers of backend conductive structures may include a plurality of layers 130a-130e that are vertically arranged and alternate with a plurality of layers 132a-132e in the z-direction (e.g., vertically alternate). The layers 130a-130e each include a layer of interconnect structures, and the layers 132a-132e each include a layer of metallization structures. The layers 130a-130e of interconnect structures may be referred to as V-layers. The layers 132a-132e of metallization structures may be referred to as M-layers.

As shown in FIG. 1, a layer 130a of interconnect structures may be a bottom-most layer of interconnect structures in the interconnect layer, and may be referred to as a via-0 (V0) layer. The interconnect structures of the layer 130a may include source/drain interconnect structures 134 that are electrically coupled and/or physically coupled to the source/drain contact structures 122, and gate interconnect structures 136 that are electrically coupled and/or physically coupled to the gate structures 116. In some implementations, gate contacts (not shown) are included between the gate structures 116 and the gate interconnect structures 136. In some implementations, the source/drain interconnect structures 134 are referred to source/drain vias (VDs), and the gate interconnect structures 136 are referred to as gate vias (VGs).

The source/drain interconnect structures 134 and the gate interconnect structures 136 may each include vias, conductive pillars, conductive columns, and/or another type of electrically conductive structures that are elongated in the z-direction. The source/drain interconnect structures 134 and the gate interconnect structures 136 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, the source/drain interconnect structures 134 and the gate interconnect structures 136 include the same material(s). In some implementations, the source/drain interconnect structures 134 include material(s) that are different from the material(s) of the gate interconnect structures 136. In some implementations, one or more liner layers are included between the surrounding dielectric layers in the interconnect layer 104. The source/drain interconnect structures 134 and the gate interconnect structures 136 may be located in an ILD layer 126 and/or in an ESL 128.

In some implementations, one or more liner layers be included between these layers and the source/drain interconnect structures 134 and the gate interconnect structures 136. The liner layer(s) may each include barrier liners, adhesion liners, and/or another type of liners. Examples of materials for the one or more liners include tantalum nitride (TaN) and/or titanium nitride (TiN), among other examples.

In some implementations, the source/drain interconnect structures 134 and the gate interconnect structures 136 are liner-free. In these implementations, the source/drain interconnect structures 134 and the gate interconnect structures 136 may be formed using a bottom-up deposition technique. The bottom-up deposition technique may include selectively depositing the material of the source/drain interconnect structures 134 and the gate interconnect structures 136 on the source/drain contacts 122 and on the gate structures 116, respectively. In this way, the material of the source/drain interconnect structures 134 and the gate interconnect structures 136 accumulates (e.g., “grows”) from the bottoms of the recesses in which the source/drain interconnect structures 134 and the gate interconnect structures 136 are formed, as opposed to the material accumulating on the sidewalls as well as on the bottoms of the recesses. The bottom-up growth of the source/drain interconnect structures 134 and the gate interconnect structures 136 enables the source/drain interconnect structures 134 and the gate interconnect structures 136 to be formed seam-free. The absence of seams in the source/drain interconnect structures 134 and the gate interconnect structures 136 occurs due to the bottom-up growth, whereas seams might otherwise occur where material is accumulated on the sidewalls of the recesses (which might merge at the top of the recesses before the recesses can be fully filled in with the material of the source/drain interconnect structures 134 and the gate interconnect structures 136).

As further shown in FIG. 1, a layer 132a of metallization structures may be a bottom-most layer of metallization structures in the interconnect layer, and may be referred to as a metal-0 (M0) layer. The metallization structures in the layer 132a (e.g., the M0 layer) may be located above and coupled to the source/drain interconnect structures 134 and the gate interconnect structures 136 in the layer 130a (e.g., the V0 layer).

The metallization structures in the layer 132a may be formed from an adhesion layer 138 and a metal layer 140. The adhesion layer 138 may be located above and/or on the ILD layer 126 of the layer 130a, and the metal layer 140 may be located above and/or on the adhesion layer 138. The adhesion layer 138 may include a tantalum nitride (TaN) adhesion layer and/or titanium nitride (TiN) adhesion layer, among other examples. The adhesion layer 138 may be included between the metal layer 140 and the source/drain interconnect structures 134 and the gate interconnect structures 136 in the layer 130a to promote adhesion of the metal layer 140 to the underlying ILD layer 126.

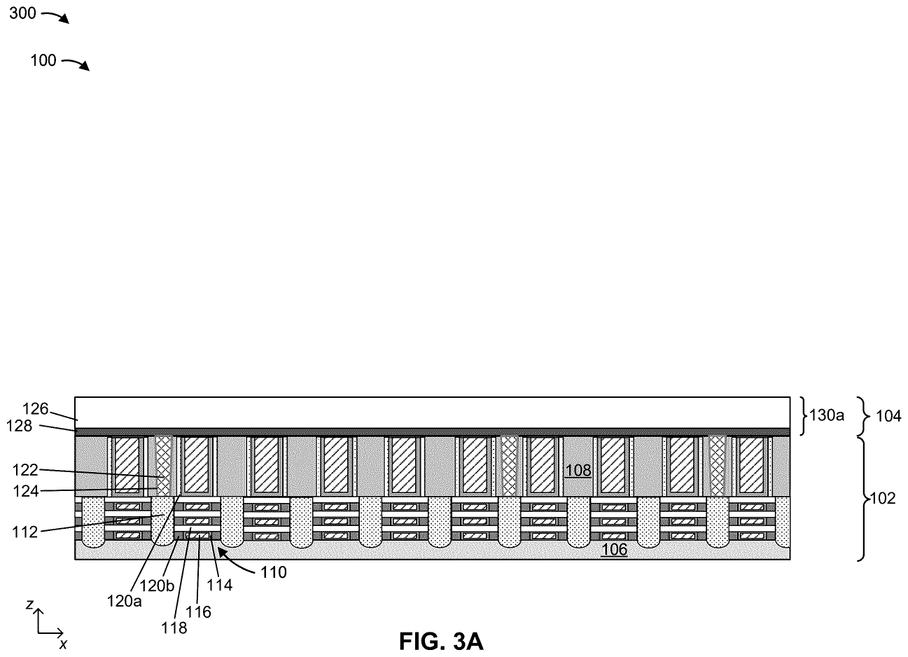

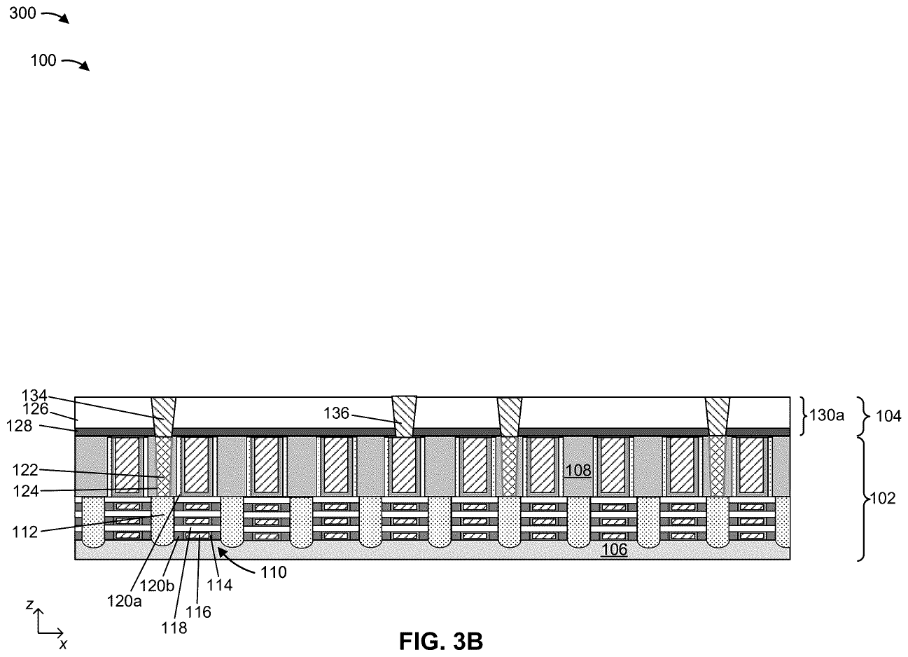

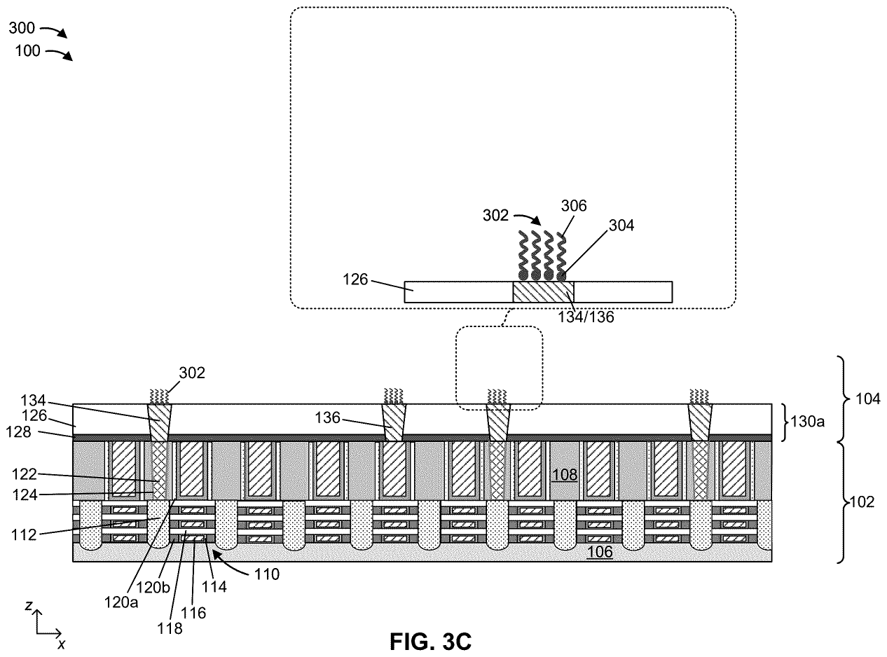

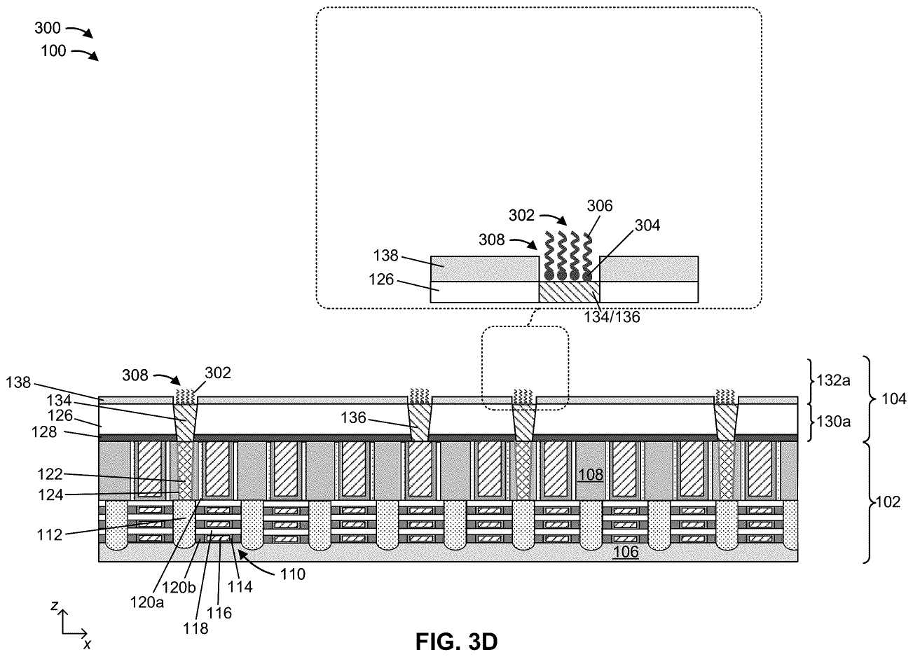

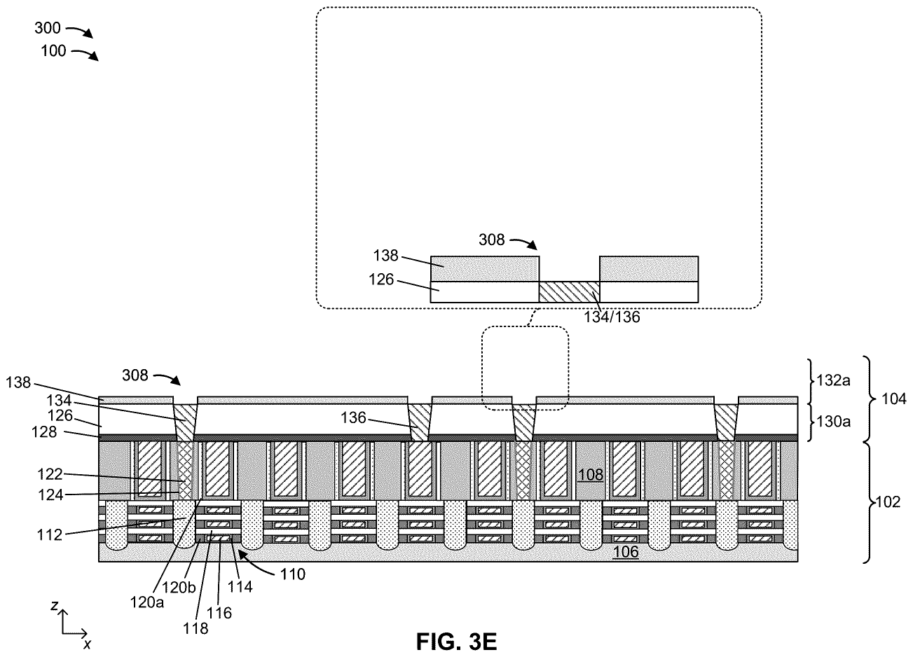

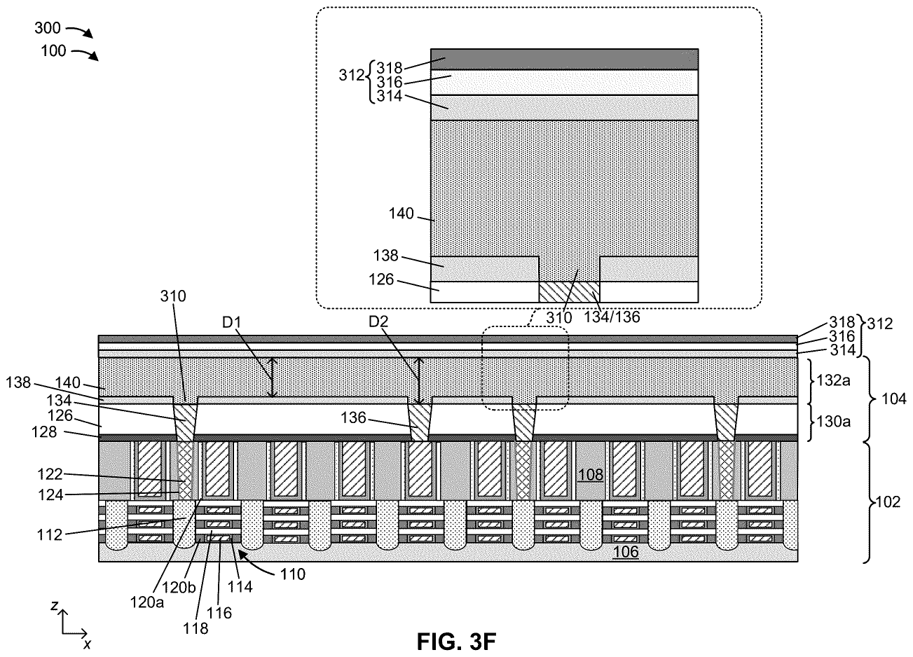

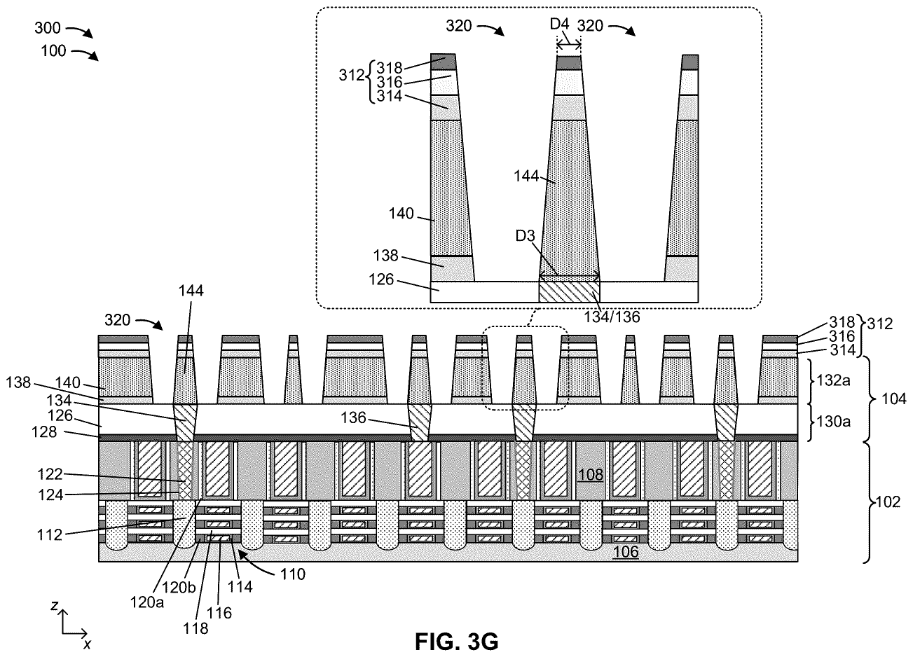

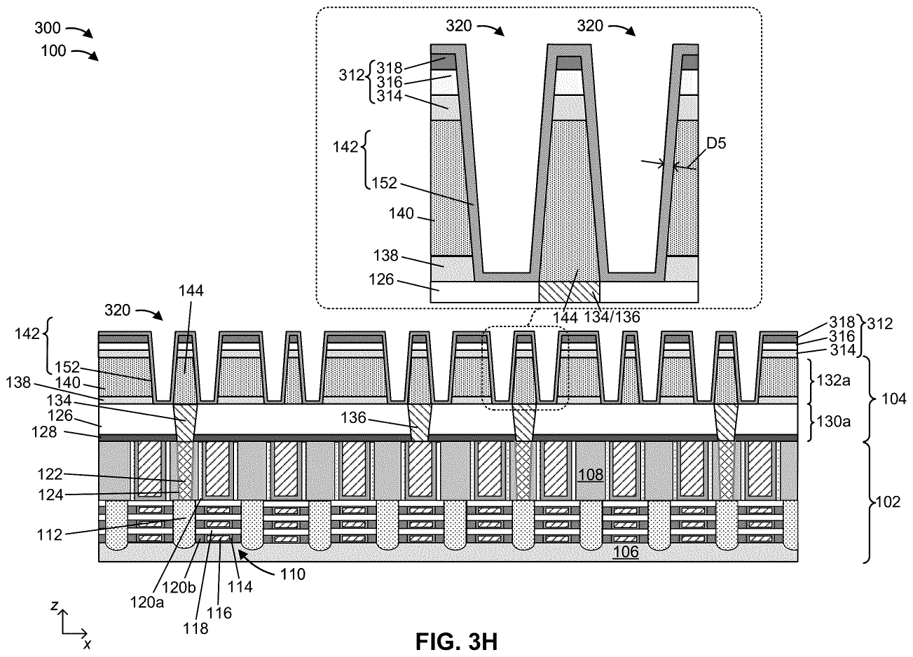

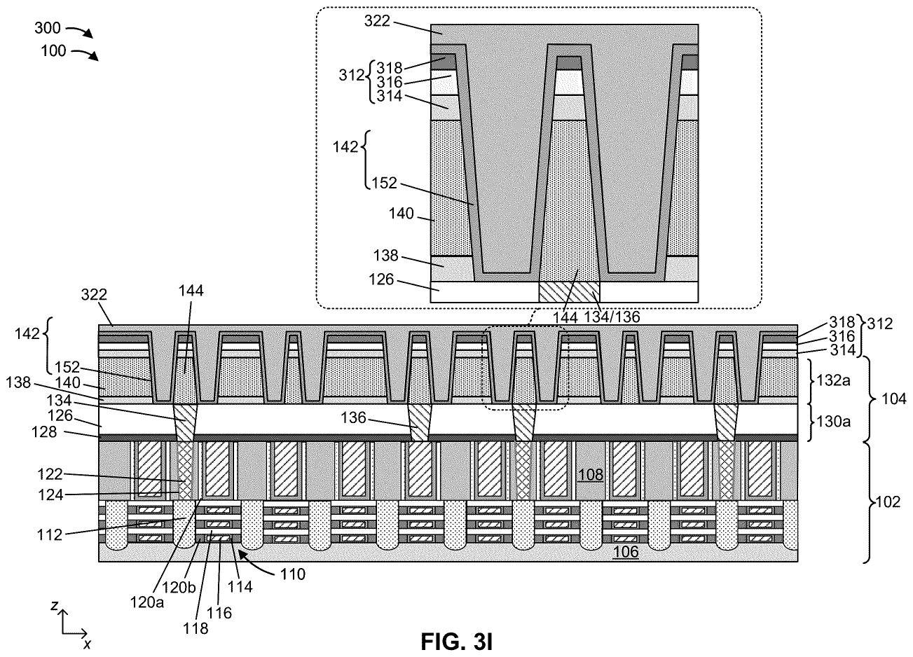

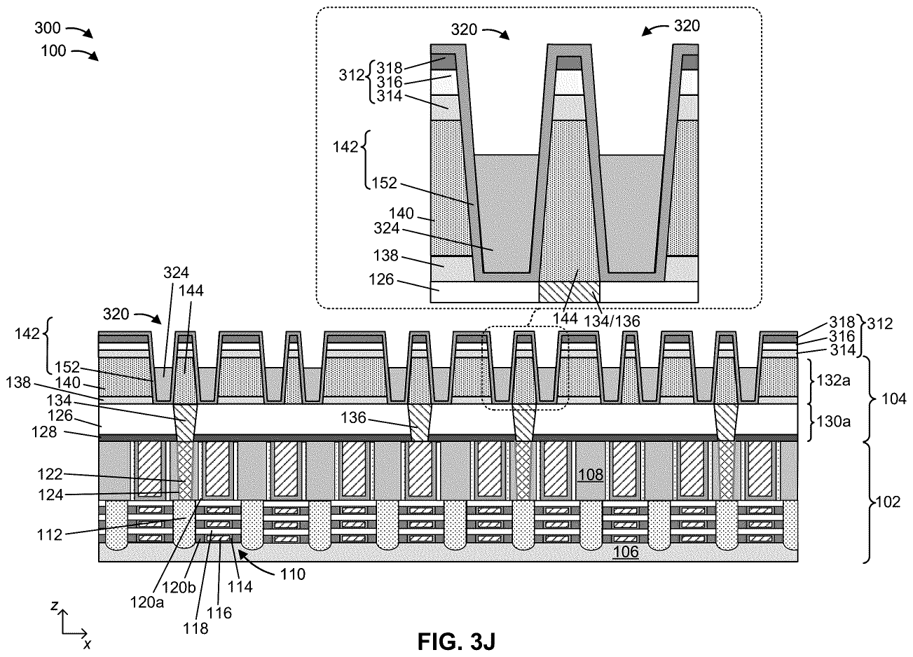

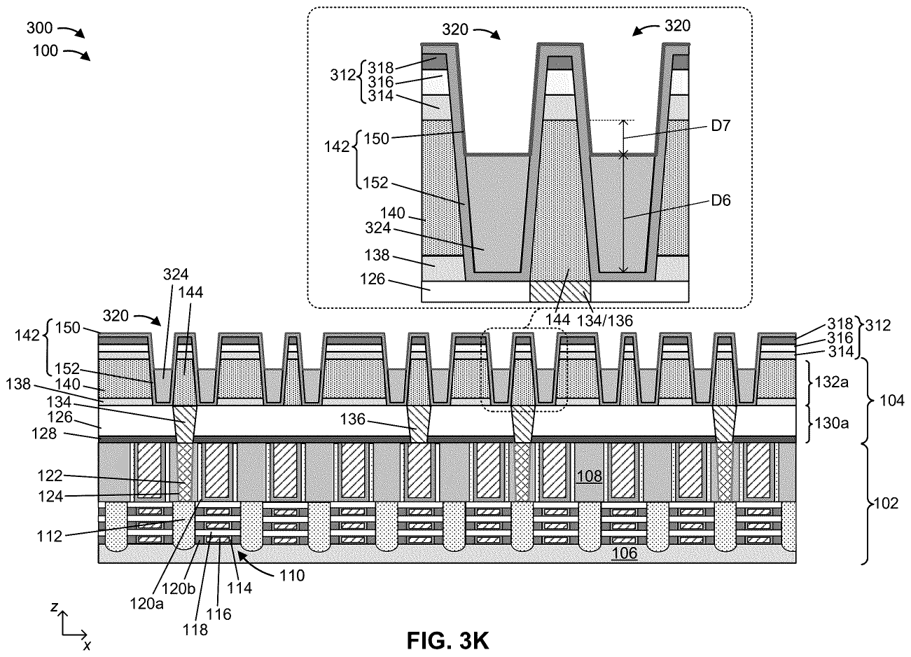

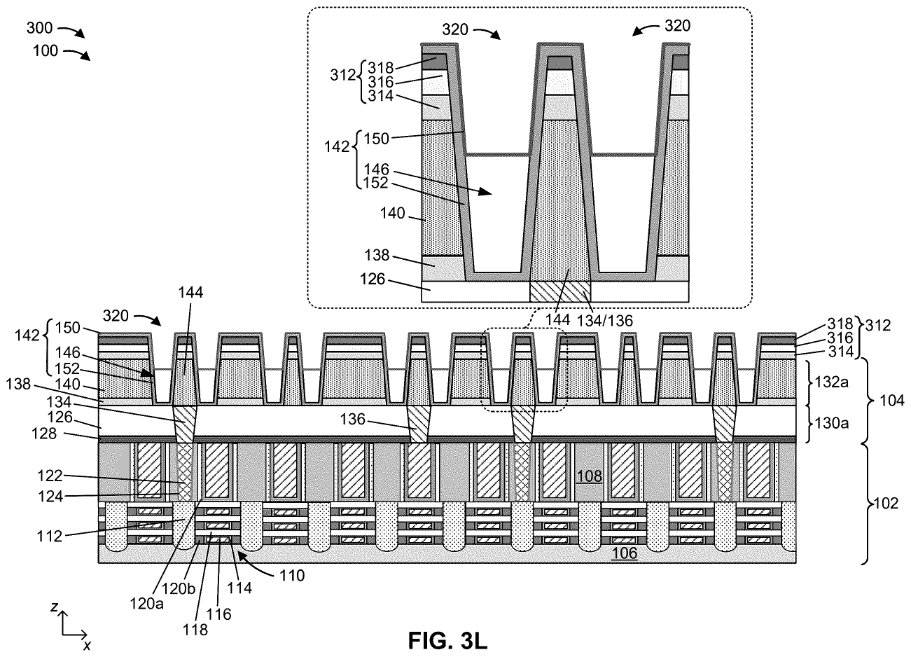

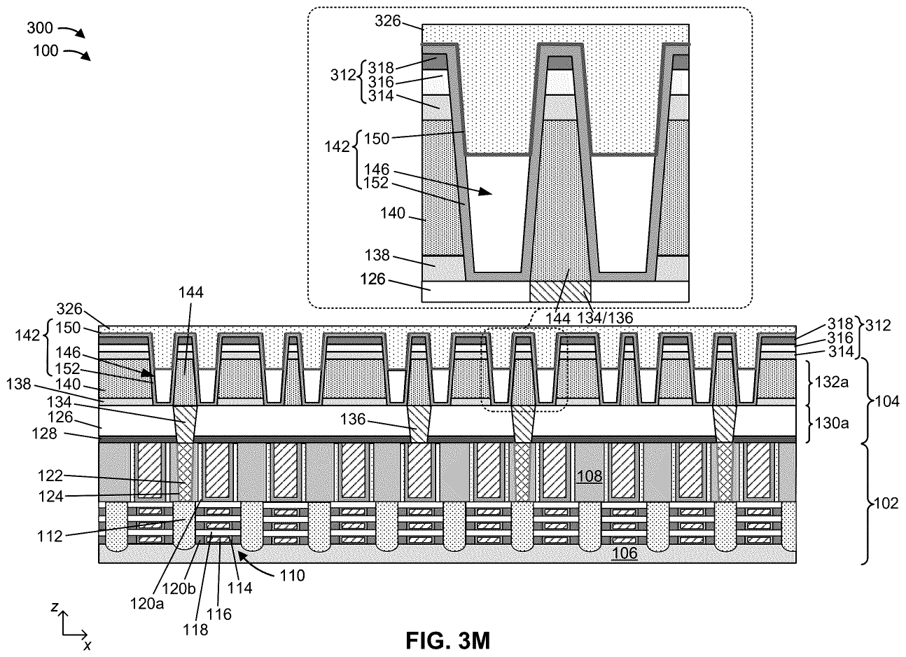

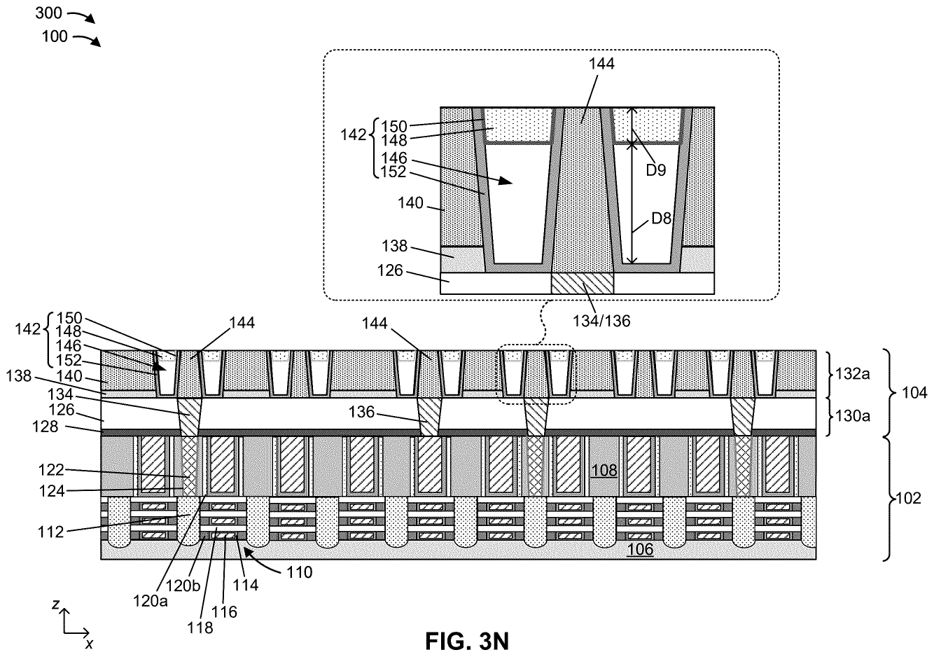

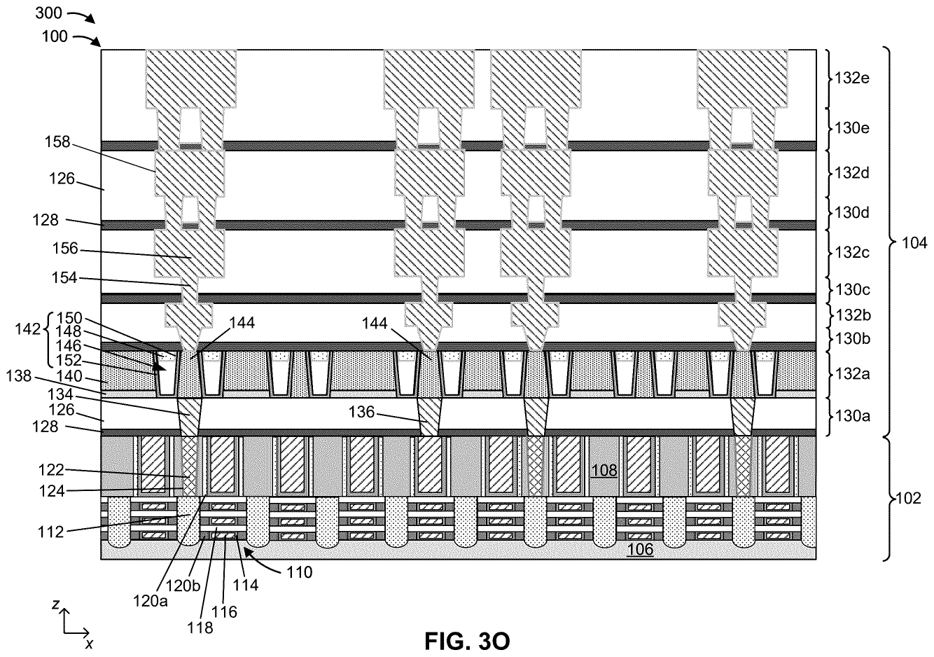

The metal layer 140 may include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. As described in connection with FIGS. 3A-3O, the metal layer 140 may be patterned and etched to form isolation regions 142 in the metal layer 140. The isolation regions 142 vertically extend through the metal layer 140 and the adhesion layer 138, and define metallization structures 144 of the layer 132a of metallization structures.

As shown in FIG. 1, the metallization structures 144 may have an inverted cross-sectional profile relative to the source/drain interconnect structures 134 and the gate interconnect structures 136 in the layer 130a of interconnect structures. In particular, the top widths of the metallization structures 144 may be less than the bottom widths of the metallization structures 144, whereas the top widths of the source/drain interconnect structures 134 and the gate interconnect structures 136 may be greater than the bottom widths of the source/drain interconnect structures 134 and the gate interconnect structures 136 in the layer 130a. This occurs because of the different processes and techniques used to form the layers 130a and 132a. For example, and as described in more detail in connection with FIGS. 3A-3O, the source/drain interconnect structures 134 and the gate interconnect structures 136 in the layer 130a may be formed by forming the ESL 128 and the ILD layer 126 of the layer 130a, etching these layers to form recesses through these layers, and forming the source/drain interconnect structures 134 and the gate interconnect structures 136 in the recesses. In contrast, and as described in more detail in connection with FIGS. 3A-3O, the adhesion layer 138 and the metal layer 140 are formed and then etched to form the isolation regions 142 that define the metallization structures 144. Thus, the isolation regions 142 have a similar cross-sectional profile as the source/drain interconnect structures 134 and the gate interconnect structures 136.

As further shown in FIG. 1, the metallization structures 144 may be included on one or more source/drain interconnect structures 134 and/or on one or more gate interconnect structures 136. A metallization structure 144 may extend through the adhesion layer 138 such that the metallization structure 144 is in direct physical contact with a top surface of a source/drain interconnect structure 134 or a top surface a gate interconnect structure 136. In other words, the interface between the metallization structure 144 and the source/drain interconnect structure 134 or the gate interconnect structure 136 may be free of the material of the adhesion layer 138. This may be achieved by forming a blocking layer on the top surfaces of the source/drain interconnect structures 134 and/or the gate interconnect structures 136 prior to formation of the adhesion layer 138, as described in greater detail in connection with FIGS. 3A-3O.

Because the blocking layer is used to inhibit formation of the adhesion layer 138 on the top surfaces of the source/drain interconnect structures 134 and/or the gate interconnect structures 136, the bottom cross-sectional width of a metallization structure 144 may be approximately equal to the top cross-sectional width of the source/drain interconnect structure 134 or the gate interconnect structure 136 on which the metallization structure 144 was formed. In other words, the metallization structure 144 may cover substantially the entirety of the top surface of the underlying source/drain interconnect structure 134 or gate interconnect structure 136. The comprehensive coverage of the metallization structure 144 on the underlying source/drain interconnect structure 134 or gate interconnect structure 136 may enable a low contact resistance to be achieved between the metallization structure 144 on and the underlying source/drain interconnect structure 134 or gate interconnect structure 136.

An isolation region 142 may include an air spacer 146 defined by the adhesion layer 138 and the metal layer 140, and that is sealed at the top of the air spacer 146 by a dielectric plug 148. The dielectric plug 148 may include a low-k dielectric material such as a silicon oxide (SiO₂). The low-k dielectric material of the dielectric plug 148, along with the air of the air spacer 146, enables a low parasitic capacitance to be achieved between metallization structures 144 electrically isolated by the isolation region 142. However, other dielectric materials may be used for the dielectric plug 148.

An isolation region 142 may include a supporting layer 150 that is formed during the process of forming the air spacers 146 and the dielectric plugs 148 of the isolation regions 142. The supporting layers 150 may include a conformal layer that supports the material of the dielectric plugs 148 as the material is deposited, so as to prevent the material of the dielectric plugs 148 from filling in the air spacers 146. The supporting layer 150 may include a dielectric material. For example, the supporting layer 150 may include an oxide material such as a silicon oxide-based material. Examples of such materials include silicon dioxide (SiO₂), silicon oxycarbide (SiOC), silicon oxynitride (SiON), and/or silicon oxycarbonitride (SiOCN), among other examples.

As further shown in FIG. 1, the isolation regions 142 may be lined with liners 152 that caps the sidewalls of the metal layer 140 and the sidewalls of the metallization structures 144. The liners 152 of the isolation regions 142 may be formed on the sidewalls of the metal layer 140 and the sidewalls of the metallization structures 144 to prevent, minimize, and/or otherwise reduce the likelihood of (and/or the extent of) oxidation of the sidewalls of the metal layer 140 and the sidewalls of the metallization structures 144. The liners 152 may extend along the sidewalls and the bottom surfaces of the air spacers 146, and along the sidewalls of the dielectric plugs 148. A liner 152 may be included between the adhesion layer 138 and an air spacer of an isolation region 142.

The liners 152 may include one or more dielectric materials. Examples of such materials include silicon dioxide (SiO₂), silicon oxycarbide (SiOC), silicon oxynitride (SiON), and/or silicon oxycarbonitride (SiOCN), among other examples.

In some implementations, the dielectric plugs 148, the supporting layers 150, and the liners 152 may be formed of different dielectric materials. For example, the liners 152 may be formed of a dielectric material that has a dielectric constant that is greater than the dielectric constant of the material of the supporting layers 152, and the dielectric material of the supporting layers 152 may have a dielectric constant that is greater than the dielectric constant of the material of the dielectric plugs 148. Other combinations of dielectric materials for the dielectric plugs 148, the supporting layers 150, and the liners 152 are within the scope of the present disclosure.

As further shown in FIG. 1, a layer 130b (e.g., a via-1 (V1) layer) of interconnect structures 154 may be included above and electrically coupled to the layer 132a (e.g., the M0 layer). A layer 132b (e.g., a metal-1 (M1) layer) of metallization structures 156 may be located above and electrically coupled to the layer 130b (e.g., the V1 layer) in the interconnect layer 104. A layer 130c (e.g., a via-2 (V2) layer) of interconnect structures 154 may be included above and electrically coupled to the layer 132b (e.g., the M1 layer). A layer 132c (e.g., a metal-2 (M2) layer) of metallization structures 156 may be located above and electrically coupled to the layer 130c (e.g., the V2 layer) in the interconnect layer 104. A layer 130d (e.g., a via-3 (V3) layer) of interconnect structures 154 may be included above and electrically coupled to the layer 132c (e.g., the M2 layer). A layer 132d (e.g., a metal-3 (M3) layer) of metallization structures 156 may be located above and electrically coupled to the layer 130d (e.g., the V3 layer) in the interconnect layer 104. A layer 130e (e.g., a via-4 (V4) layer) of interconnect structures 154 may be included above and electrically coupled to the layer 132d (e.g., the M3 layer). A layer 132e (e.g., a metal-4 (M4) layer) of metallization structures 156 may be located above and electrically coupled to the layer 130e (e.g., the V4 layer) in the interconnect layer 104.

In some implementations, the interconnect structures may include a different quantity of (e.g., greater, fewer) layers 130a-130e of interconnect structures (e.g., V-layers) and/or may include a different quantity of (e.g., greater, fewer) layers 132a-132e of metallization structures (e.g., M-layers) than shown in the example in FIG. 1.

The interconnect structures 154 may include a combination of vias, interconnects, and/or other types of conductive structures. The metallization structures 156 may include a combination of trenches, metallization layers, conductive traces, and/or other types of conductive structures. The interconnect structures 154 and the metallization structures 156 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers 158 are included between the dielectric layers of the interconnect layer 104 and the interconnect structures 154, and/or between the dielectric layers of the interconnect layer 104 the metallization structures 156. The one or more liner layers 158 may include barrier liners, adhesion liners, and/or another type of liners. Examples of materials for the one or more liner layers 158 include tantalum nitride (TaN) and/or titanium nitride (TiN), among other examples. In some implementations, the electrical conductivity of the material (e.g., TaN) of one or more liner layers 158 may be less than the electrical conductivity of the material of the metal-oxide liners 152 (e.g., ruthenium oxide (RuOx)).

In some implementations, the topmost layer of backend conductive structures (e.g., a topmost layer of metallization structures 156, a topmost layer of interconnect structures 154) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of backend conductive structures (e.g., a topmost layer of metallization structures 156, a topmost layer of interconnect structures 154) may be coupled to bonding structures, such as bonding pads and/or bonding vias.

As indicated above, FIG. 1 is provided as an example. Other examples may differ from what is described with regard to FIG. 1.

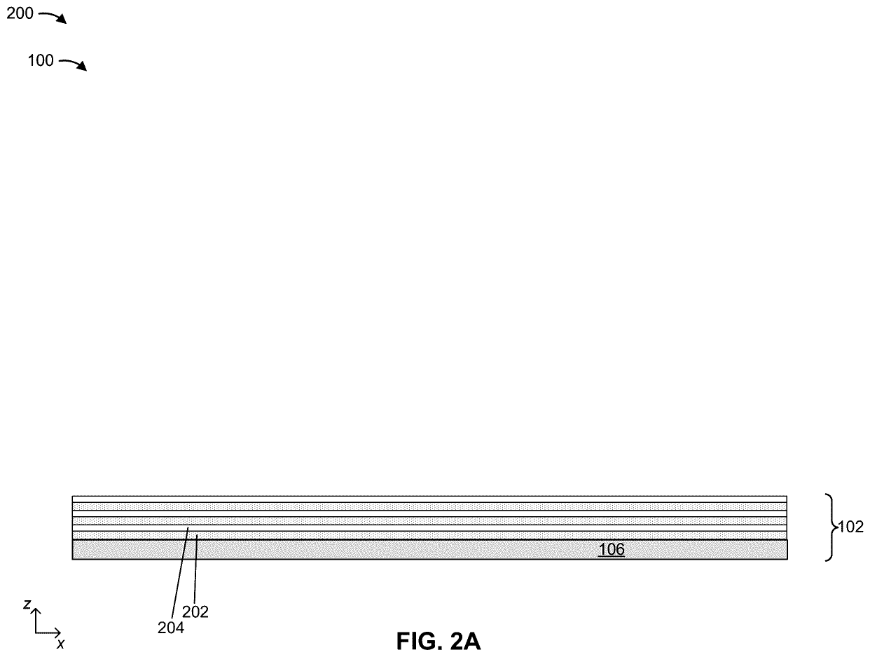

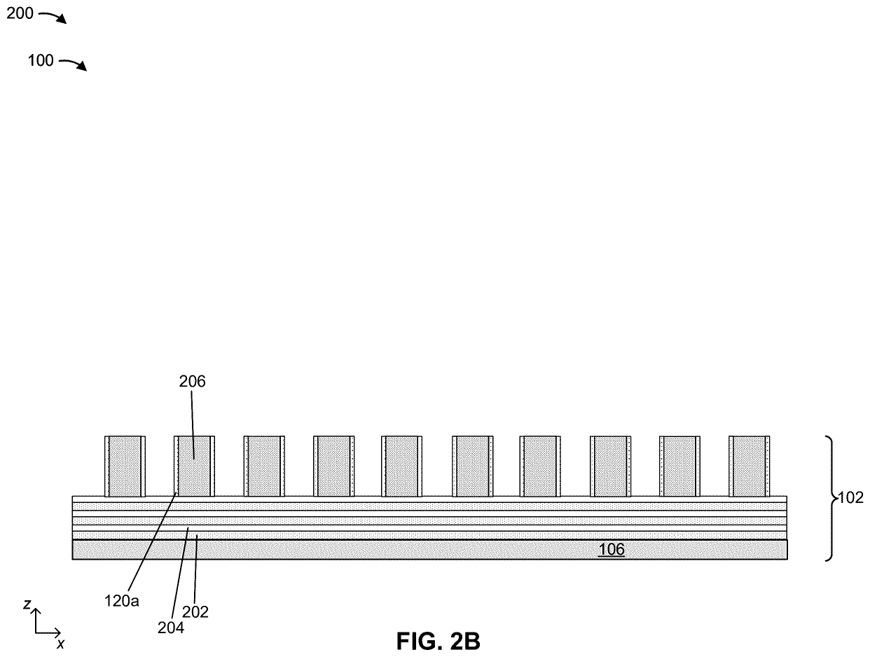

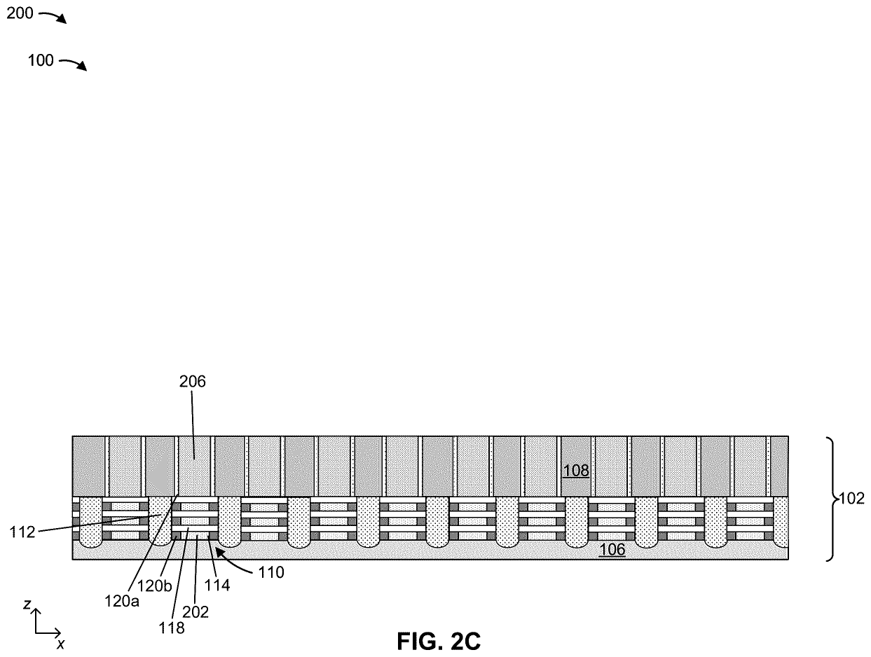

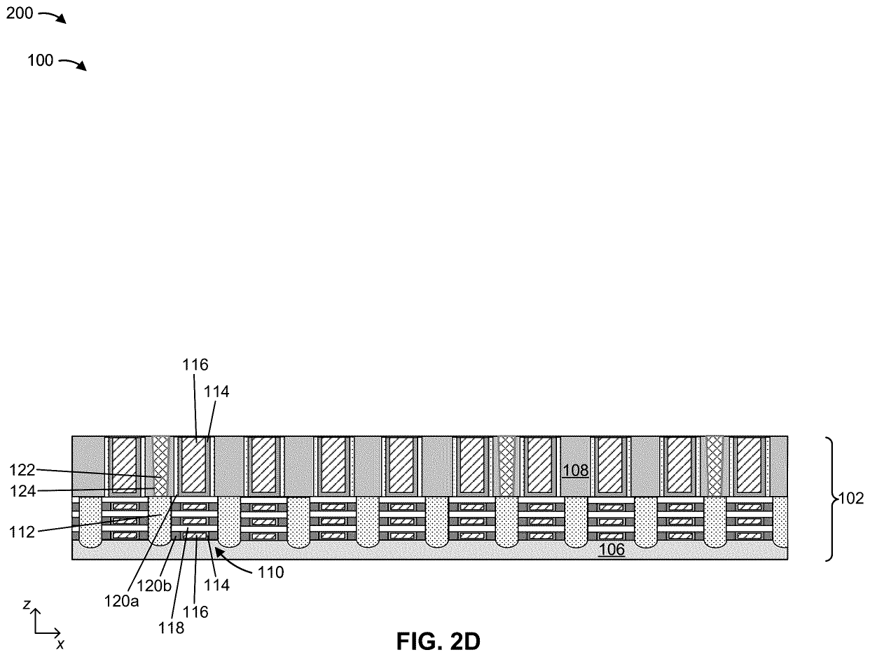

FIGS. 2A-2D are diagrams of an example implementation 200 of forming a device layer 102 (or a portion thereof) the semiconductor device 100 described herein. In some implementations, one or more of the semiconductor processing operations described in connection with FIGS. 2A-2D may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 2A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

A layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 202 and nanostructure channel layers 204 above the substrate layer 106. The quantity of the sacrificial layers 202 and the quantity of the nanostructure channel layers 204 illustrated in FIG. 2A are examples, and other quantities of the sacrificial layers 202 and the nanostructure channel layers 204 are within the scope of the present disclosure.

The sacrificial layers 202 enable a vertical distance to be defined between adjacent nanostructure channels that are formed from the nanostructure channel layers 204, and serve as placeholder layers for subsequently-formed gate structures of the integrated circuit devices 110 of the semiconductor device 100 that are formed around the nanostructure channels.

The sacrificial layers 202 include a first material composition, and the nanostructure channel layers 204 include a second material composition. In some implementations, the first material composition and the second material composition are the same material composition. In some implementations, the first material composition and the second material composition are different material compositions. As an example, the sacrificial layers 202 may include silicon germanium (SiGe) and the nanostructure channel layers 204 may include silicon (Si). This enables the sacrificial layers 202 and/or the nanostructure channel layers 204 to be selectively etched (e.g., enables the sacrificial layers 202 and not the nanostructure channel layers 204 to be etched, enables the nanostructure channel layers 204 and not the sacrificial layers 202 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 202 and/or the nanostructure channel layers 204 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 202 and/or the nanostructure channel layers 204 may be deposited by chemical vapor deposition (CVD), physical vapor deposition (PVD), atomic layer deposition (ALD), and/or another suitable deposition technique.

In the y-direction, which is not visible in the view in FIG. 2A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 2B, dummy gate structures 206 (also referred to as dummy gate stacks or temporary gate structures) may be formed over portions of the layer stack of sacrificial layers 202 and nanostructure channel layers 204. The dummy gate structures 206 may extend in the y-direction and may be arranged in the x-direction such that the dummy gate structures are approximately perpendicular to the fin structures. The dummy gate structures 206 are sacrificial structures that are to be replaced by replacement gate structures or replacement gate stacks at a subsequent processing stage for the integrated circuit devices 110 of the semiconductor device 100. The dummy gate structures 206 may also be used to define source/drain (S/D) recesses in which source/drain regions of the nanostructure transistors are formed in the layer stack of sacrificial layers 202 and nanostructure channel layers 204.

The dummy gate structures 206 may include polycrystalline silicon (polysilicon or PO) or another material. The layers of the dummy gate structures 206 may be formed using various semiconductor processing techniques such depositing the layers of the dummy gate structures 206, patterning the layers of the dummy gate structures 206 to define the dummy gate structures 206, and/or other semiconductor processing techniques. The sidewall spacers 120a may be formed on the sidewalls of the dummy gate structures 206.

As shown in FIG. 2C, the source/drain regions 112 of the integrated circuit devices 110 are formed in the layer stack of sacrificial layers 202 and nanostructure channel layers 204. To form the source/drain regions 112, source/drain recesses may be formed through the layer stack of sacrificial layers 202 and nanostructure channel layers 204 in an etch operation. The source/drain recesses may be formed on opposing sides of a dummy gate structure 206 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 202 that are exposed in the source/drain recesses may be laterally etched in an etch operation, thereby forming cavities in the ends of the sacrificial layers 202. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 2C, the dielectric layer 108 may be formed over the source/drain regions 112 and around the dummy gate structures 206. The dielectric layer 108 may fill in areas between the dummy gate structures 206. In some implementations, a contact etch stop layer (CESL) is conformally deposited (e.g., by a deposition tool) over the source/drain regions 112 prior to formation of the dielectric layer 108. The dielectric layer 108 is then formed on the CESL. The CESL may provide a mechanism to stop an etch process when forming source/drain contacts 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 2D, a replacement gate process may be performed to replace the dummy gate structures 206 with the gate structures 116 of the integrated circuit devices 110. A dummy gate removal operation may be performed to remove the dummy gate structures 206 from the semiconductor device 100. The removal of the dummy gate structures 206 leaves behind openings (or recesses) in the dielectric layer 108, and provides access to the underlying sacrificial layers 202. The dummy gate structures 206 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 202 (e.g., the silicon germanium layers). This results in openings between the channel layers 118 (e.g., the areas around the channel layers 118). The sacrificial layers 202 may be removed through the spaces that were previously occupied by the dummy gate structures 206. The nanostructure release operation may include the use of an etch tool to perform an etch operation to remove the sacrificial layers 202 based on a difference in etch selectivity between the material of the sacrificial layers 202 and the material of the channel layers 118, and between the material of the sacrificial layers 202 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 202 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 206. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 2D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a chemical-mechanical planarization (CMP) operation) to planarize the source/drain contact structures 122 after the source/drain contact structures 122 are deposited such that the tops of the source/drain contact structures 122 are approximately co-planar with the top of the dielectric layer 108.

As indicated above, FIGS. 2A-2D are provided as an example. Other examples may differ from what is described with regard to FIGS. 2A-2D.

FIGS. 3A-3O are diagrams of an example implementation 300 of forming an interconnect layer 104 (or a portion thereof) of the semiconductor device 100 described herein. In particular, the example implementation 300 includes an example of forming the interconnect layer 104 (e.g., the back end region or BEOL region) of the semiconductor device 100. In some implementations, one or more of the semiconductor processing operations described in connection with FIGS. 3A-3O may be performed after one or more processes described in connection with FIGS. 2A-2C. In some implementations, one or more of the semiconductor processing operations described in connection with FIGS. 3A-3O may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the interconnect layer 104 of the semiconductor device 100 is formed above the dielectric layer 108 of the device layer 102. The layer 130a of interconnect structures (e.g., the bottom-most layer of interconnect structures of the interconnect layer 104) may be formed above and/or on the dielectric layer 108. To form the layer 130a, an ESL 128 may be formed over and/or on the dielectric layer 108 such that the ESL 128 covers the gate structures 116 and the source/drain contact structures 122 of the integrated circuit devices 110. An ILD layer 126 may be formed over and/or on the ESL 128.

A deposition tool may be used to deposit the ESL 128 and/or the ILD layer 126 using a PVD technique, an ALD technique, a CVD technique, an oxidation technique, and/or another suitable deposition technique. The ESL 128 and/or the ILD layer 126 may be deposited in one or more deposition operations. In some implementations, a planarization tool may be used to perform a planarization operation (e.g., a CMP operation) to planarize the ESL 128 and/or the ILD layer 126 after the ESL 128 and/or the ILD layer 126 is deposited.

As shown in FIG. 3B, the source/drain interconnect structures 134 and/or the gate interconnect structures 136 of the layer 130a of interconnect structures (e.g., the V0 layer) may be formed in and/or through the ILD layer 126 and the ESL 128. To form the source/drain interconnect structures 134 and/or the gate interconnect structures 136, recesses may be formed in and/or through the ILD layer 126 and the ESL 128. In some implementations, one or more recesses may be formed above one or more source/drain contact structures 122 such that the one or more source/drain contact structures 122 are exposed through the recesses. In some implementations, one or more recesses may be formed above one or more gate structures 116 such that the one or more gate structures 116 are exposed through the recesses.

In some implementations, a pattern in a photoresist layer is used to etch the ILD layer 126 and/or the ESL 128 of the layer 130a to form the recesses. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 126 and/or the ESL 128 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

The source/drain interconnect structures 134 and/or the gate interconnect structures 136 of the layer 130a of interconnect structures may be formed in the recesses. A deposition tool may be used to deposit the source/drain interconnect structures 134 and/or the gate interconnect structures 136 using a CVD technique, a PVD technique, an ALD technique, an electroplating technique, and/or another suitable deposition technique. The source/drain interconnect structures 134 and/or the gate interconnect structures 136 may be deposited in one or more deposition operations. In some implementations, a seed layer is first deposited, and the source/drain interconnect structures 134 and/or the gate interconnect structures 136 are deposited on the seed layer. In some implementations, a planarization tool is used to perform a planarization operation (e.g., a CMP operation) to planarize the source/drain interconnect structures 134 and/or the gate interconnect structures 136 after the source/drain interconnect structures 134 and/or the gate interconnect structures 136 are deposited.

As shown in FIG. 3C, a blocking layer 302 may be selectively formed on exposed surfaces of the source/drain interconnect structures 134 and/or on exposed surfaces of the gate interconnect structures 136. The blocking layer 302 may be selectively formed in that the blocking layer 302 includes a material that inhibits adsorption of the blocking layer 302 onto the ILD layer 126, and that promotes adsorption of the blocking layer 302 onto the exposed surfaces of the source/drain interconnect structures 134 and/or the gate interconnect structures 136.

As shown in a detailed view in FIG. 3C, the blocking layer 302 may include a self-assembled monolayer film that includes an anchor group 304 and a side-chain group 306. The self-assembled monolayer film is a “monolayer” film in that the self-assembled monolayer film may have a single-molecule thickness (e.g., a thickness corresponding to a one-molecule thick layer of a material of the blocking layer 302).

The anchor group 304 of the self-assembled monolayer film inhibits adsorption of the blocking layer 302 onto the ILD layer 126, and that promotes adsorption of the blocking layer 302 onto the exposed surfaces of the source/drain interconnect structures 134 and/or the gate interconnect structures 136. The anchor group may include a carbonyl group (e.g., a —COH group or —CO group), a nitrile group (e.g., a —CN group), an amide group (e.g., a —CON group), and/or another organic functional group that adheres to metal materials and that does not readily adhere to dielectric materials. In some implementations, the adsorption selectivity of the anchor group 304 of the self-assembled monolayer film may be included in a range of 20:1 (e.g., 20:1 adsorption onto the metal material of the source/drain interconnect structures 134 and/or the gate interconnect structures 136 to adsorption onto the dielectric material of the ILD layer 126) to approximately 70:1, to achieve sufficient deposition selectivity for the blocking layer 302. However, other values and ranges are within the scope of the present disclosure.

The side chain group 306 may include a hydrocarbon group such as an alkyl group and/or an aryl group, and/or another functional group that blocks or inhibits precursors of a material of the adhesion layer 138 from being adsorbed onto the exposed surfaces of the source/drain interconnect structures 134 and/or the gate interconnect structures 136.

In some implementations, the blocking layer 302 is formed by depositing a solution that contains material of the blocking layer 302 onto the exposed surfaces of the source/drain interconnect structures 134 and/or the gate interconnect structures 136 using a spin-coating technique. In some implementations, a pre-cleaning operation uses isopropyl alcohol (IPA) or another cleaning agent to pre-clean the exposed surfaces of the source/drain interconnect structures 134 and/or the gate interconnect structures 136 prior to depositing the solution.

The solution may include the material of the blocking layer 302 dissolved in a solvent, which enables the material of the blocking layer 302 to be distributed across the exposed surfaces of the source/drain interconnect structures 134 and/or the gate interconnect structures 136. The solvent may include a gamma-butyrolactone (GBL) solvent, a diethylformamide (DEF) solvent, a propylene glycol methyl ether acetate (PGMEA) solvent, a propylene glycol methyl ether (PGME) solvent, and/or another suitable solvent.

Once the exposed surfaces of the source/drain interconnect structures 134 and/or the gate interconnect structures 136 are coated with the solvent, a spin dry operation may be performed to cure the solution by evaporating the solvent such that the material of the blocking layer 302 remains on the exposed surfaces of the source/drain interconnect structures 134 and/or the gate interconnect structures 136. The molecules of the material spontaneously self-assemble into a monolayer, thereby forming a self-assembled monolayer film. In some implementations, another cleaning operation (e.g., using IPA or another cleaning agent) is performed prior to the spin dry operation. In some implementations, the spin dry operation is performed in a range of approximately 200 revolutions per minute (rpm) to approximately 1000 rpm. However, other values and ranges for the spin dry operation are within the scope of the present disclosure.

In some implementations, the blocking layer 302 is formed to a thickness that is included in a range of approximately 0.1 angstroms to approximately 10 angstroms. If the thickness of the blocking layer 302 is less than approximately 0.1 angstroms, the blocking layer 302 may not sufficiently block or inhibit formation of the adhesion layer 138 on the exposed surfaces of the source/drain interconnect structures 134 and/or the gate interconnect structures 136, resulting in increased contact resistance between the metallization structures 144 that are to be subsequently formed on the source/drain interconnect structures 134 and/or on the gate interconnect structures 136. If the thickness of the blocking layer 302 is greater than approximately 10 angstroms, the blocking layer 302 may be too thick to be adequately removed from the exposed surfaces of the source/drain interconnect structures 134 and/or the gate interconnect structures 136. If the thickness of the blocking layer 302 is included in the range of approximately 0.1 angstroms to approximately 10 angstroms, the blocking layer 302 may sufficiently block or inhibit formation of the adhesion layer 138 on the exposed surfaces of the source/drain interconnect structures 134 and/or the gate interconnect structures 136, and may be sufficiently removed from the exposed surfaces of the source/drain interconnect structures 134 and/or the gate interconnect structures 136. However, other values for the thickness of the blocking layer 302, and ranges other than approximately 0.1 angstroms to approximately 10 angstroms, are within the scope of the present disclosure.

As shown in FIG. 3D, the adhesion layer 138 of the layer 132a may be formed over and/or on the ILD layer 126 such that the adhesion layer 138 covers the ILD layer 126. However, the blocking layer 302 inhibits formation of the adhesion layer 138 on the exposed surfaces of the source/drain interconnect structures 134 and/or the gate interconnect structures 136. In particular, the side chain group 306 of the blocking layer 302 inhibits adsorption of material of the adhesion layer 138 onto the exposed surfaces of the source/drain interconnect structures 134 and/or the gate interconnect structures 136, resulting in formation of openings 308 in the adhesion layer 138 over the top surfaces of the source/drain interconnect structures 134 and/or the gate interconnect structures 136.

A deposition tool may be used to deposit the adhesion layer 138 using a CVD technique, a PVD technique, an ALD technique, and/or another suitable deposition technique. In some implementations, a planarization tool is used to perform a planarization operation (e.g., a CMP operation) to planarize the adhesion layer 138 after the adhesion layer 138 is deposited.

As shown in FIG. 3E, the blocking layer 302 may be removed from the exposed surfaces of the source/drain interconnect structures 134 and/or the gate interconnect structures 136 after formation of the adhesion layer 138. Various techniques may be used to remove the blocking layer 302. In some implementations, a thermal decomposition operation may be performed to remove the blocking layer 302. The thermal decomposition operation may include heating the blocking layer 302 to a temperature that is included in a range of approximately 300 degrees Celsius to approximately 500 degrees Celsius to decompose the hydrocarbon chains in the blocking layer 302. Decomposing the side chain group 306 (e.g., the hydrocarbon chains) in the blocking layer 302 results in desorption of the blocking layer 302 from the exposed surfaces of the source/drain interconnect structures 134 and/or the gate interconnect structures 136.

In some implementations, a plasma treatment operation may be performed on the blocking layer 302 to remove the blocking layer 302. The plasma treatment operation may include the use of a plasma (e.g., an oxygen-based plasma, a nitrogen-based plasma) to clean the exposed surfaces of the source/drain interconnect structures 134 and/or the gate interconnect structures 136. This results in the blocking layer 302 being stripped from the exposed surfaces of the source/drain interconnect structures 134 and/or the gate interconnect structures 136.

In some implementations, the blocking layer 302 is fully removed from the exposed surfaces of the source/drain interconnect structures 134 and/or the gate interconnect structures 136. In some implementations, removal of the blocking layer 302 may leave behind a self-assembled monolayer film residue on the exposed surfaces of the source/drain interconnect structures 134 and/or the gate interconnect structures 136. The self-assembled monolayer film residue may include residual anchoring groups of the blocking layer 302 that remain adsorbed on the exposed surfaces of the source/drain interconnect structures 134 and/or the gate interconnect structures 136. The residual anchoring groups may include ligands of one or more elements of the anchor group 304 of the blocking layer 302.

As shown in FIGS. 3F and 3G, the layer 132a of metallization structures (e.g., the M0 layer) of the interconnect layer 104 may be formed above the layer 130a of interconnect structures. As shown in FIG. 3F, the metal layer 140 of the layer 132a may be formed over and/or on the adhesion layer 138. Portions 310 of the metal layer 140 are formed in the openings 308 through the adhesion layer 138. In other words, the portions 310 of the metal layer 140 extend through the adhesion layer 138 and are formed directly on and in contact with the top surfaces of the source/drain interconnect structures 134 and/or the gate interconnect structures 136.

A deposition tool may be used to deposit the metal layer 140 using a CVD technique, a PVD technique, an ALD technique, an electroplating technique, and/or another suitable deposition technique. In some implementations, a planarization tool is used to perform a planarization operation (e.g., a CMP operation) to planarize the metal layer 140 after the metal layer 140 is deposited.

In some implementations, the metal layer 140 is deposited to a thickness (indicated in FIG. 3F as a dimension D1) on the adhesion layer 138 that is included in a range of approximately 15 nanometers to approximately 40 nanometers. However, other values and ranges are within the scope of the present disclosure. The thickness (indicated in FIG. 3F as a dimension D2) of the metal layer 140 deposited in the openings 308 through the adhesion layer 138 is greater than the thickness of the metal layer 140 deposited on the adhesion layer 138, and may be included in a range of approximately 16 nanometers to approximately 42 nanometers. However, other values and ranges are within the scope of the present disclosure.

In some implementations, the metal layer 140 has an as-deposited polycrystalline structure. In some implementations, the adhesion layer 138 is deposited using ALD, resulting in a large grain size for the adhesion layer 138. The large grain size of the adhesion layer 138 promotes formation of larger grain sizes in the metal layer 140 than if the adhesion layer 138 were deposited using another deposition technique such as PVD. Larger grain sizes in the metal layer 140 may enable a lower line resistance (and thus, a lower resistance-capacitance (RC) time constant) to be achieved for the metallization structures 144 that are subsequently formed from the metal layer 140.

As further shown in FIG. 3F, a patterning stack 312 may be formed over and/or on the metal layer 140. The patterning stack 312 may include one or more patterning layers 314-318. The patterning layers 314-318 may include different materials to enable a pattern to be formed in the patterning stack 312 and used to etch the metal layer 140 to define the metallization structures 144 of the layer 132a. In some implementations, the patterning layer 314 may include a titanium nitride (TiN) layer, the patterning layer 316 may include a silicon nitride (SiₓN_{y}) layer, and/or the patterning layer 318 may include a silicon oxide (SiOₓ) layer. However, other combinations of materials for the patterning layers 314-318 are within the scope of the present disclosure.

A deposition tool may be used to deposit the patterning layers 314-318 of the patterning stack 312 using a CVD technique, a PVD technique, an ALD technique, an oxidation technique, and/or another suitable deposition technique. In some implementations, a planarization tool is used to perform a planarization operation (e.g., a CMP operation) to planarize the patterning layer 314, the patterning layer 316, and/or the patterning layer 318 after the patterning layer 314, the patterning layer 316, and/or the patterning layer 318 is deposited.

As shown in FIG. 3G, the patterning layers 314-318 of the patterning stack 312 may be used to form recesses 320 through the metal layer 140 and through the adhesion layer 138 to define the metallization structures 144 of the layer 132a of metallization structures. In some implementations, a recess 320 is formed adjacent to and/or around a source/drain interconnect structure 134 to define a metallization structure 144 above and/or on the source/drain interconnect structure 134. In some implementations, a recess 320 is formed adjacent to and/or around a gate interconnect structure 136 to define a metallization structure 144 above and/or on the gate interconnect structure 136.

In some implementations, a pattern in a photoresist layer is used to etch the patterning layers 314-318 of the patterning stack 312 to transfer the pattern to the patterning layers 314-318 of the patterning stack 312. In these implementations, a deposition tool may be used to form the photoresist layer on the patterning stack 312 (e.g., on the patterning layer 318) (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the patterning layers 314-318 of the patterning stack 312 based on the pattern to transfer the pattern to the patterning stack 312.

The pattern transferred to the patterning layers 314-318 of the patterning stack 312 may be used to etch the metal layer 140 and the adhesion layer 138 to form the recesses 320. In some implementations, the etch operation includes a dry etch operation (e.g., a plasma-based etch operation, a gas-based etch operation), a wet chemical etch operation, and/or another type of etch operation.

As shown in FIG. 3G, the recesses 320 may have a similar tapered cross-sectional profile as the source/drain interconnect structures 134 and the gate interconnect structures 136 of the layer 130a. In particular, top widths of the recesses 320 may be greater than bottom widths of the recesses 320 such that the widths of the recesses 320 decrease from tops of the recesses 320 to the bottom of the recesses 320.

Conversely, the metallization structures 144 have an inverted cross-sectional profile relative to the recesses 320, the source/drain interconnect structures 134, and the gate interconnect structures 136. In particular, bottom widths of the metallization structures 144 (indicated in FIG. 3G as a dimension D3) may be greater than top widths of the metallization structures 144 (indicated in FIG. 3G as dimension D4) such that the widths of the metallization structures 144 increase from tops of the metallization structures 144 to the bottom of the metallization structures 144. In some implementations, the bottom width (dimension D3) of a metallization structure 144 is included in a range of approximately 8 nanometers to approximately 12 nanometers. However, other values and ranges are within the scope of the present disclosure. In some implementations, the top width (dimension D4) of a metallization structure 144 is included in a range of approximately 6 nanometers to approximately 10 nanometers. However, other values and ranges are within the scope of the present disclosure. In some implementations, a ratio of a bottom width to a top width (D3:D4) of a metallization structure 144 is included in a range of approximately 4:3 to approximately 6:5. However, other values and ranges are within the scope of the present disclosure.

As shown in FIG. 3H, the liner 152 is formed on sidewalls and on bottom surfaces of the recesses 320. Thus, the liner 152 may be deposited on sidewalls of the metal layer 140 and sidewalls of the metallization structures 144. The liner 152 may also extend across the top surface of the patterning layer 318 between the recesses 320.

In some implementations, a deposition tool is used to deposit the material of the liner 152 using a CVD technique, a PVD technique, an ALD technique, and/or another suitable deposition technique. In some implementations, the liner 152 is deposited to a thickness (indicated in FIG. 3H as a dimension D5) that is included in a range of approximately 0.5 nanometers to approximately 3 nanometers. However, other values and ranges are within the scope of the present disclosure.

As shown in FIG. 3I, the recesses 320 may be filled with material of a sacrificial layer 322. The material of the sacrificial layer 322 may be deposited on the liner 152. The sacrificial layer 322 may include a polymer material and/or another type of material that enables the sacrificial layer 322 to be subsequently removed with minimal to no removal of materials surrounding the sacrificial layer 322. For example, the sacrificial layer 322 may include a silicon-based polymer material, such as an organosilane (e.g., a silicon-based hydrocarbon (CₓH_{y})). However, other polymer materials are within the scope of the present disclosure.

In some implementations, a deposition tool is used to deposit the material of the sacrificial layer 322 using a CVD technique, a PVD technique, an ALD technique, and/or another suitable deposition technique. In some implementations, a deposition tool is used to dispense the material of the sacrificial layer 322 into the recesses 320 such that the sacrificial layer 322 is in contact with the metal-oxide liners 152 in the recesses 320. In some implementations, a deposition tool is used to dispense the material of the sacrificial layer 322 into the recesses 320 and a curing agent to cure the material of the sacrificial layer 322. The sacrificial layer 322 may be formed such that the sacrificial layer 322 fully fills the recesses 320 and extends above (and merges above) the recesses 320.

As shown in FIG. 3J, a portion of the sacrificial layer 322 (e.g., the sacrificial polymer layer) may be removed to form sacrificial plugs 324 in the recesses 320. The sacrificial plugs 324 (e.g., sacrificial polymer plugs) partially fill the recesses 320, leaving room at the top of the recesses 320 for additional material to be deposited in the recesses 320.

In some implementations, an etch tool may be used to perform an etch operation (e.g., etch back operation) to remove the portion of the sacrificial layer 322 to form the sacrificial plugs 324. In some implementations, the etch operation includes a wet etch operation, a dry etch operation, a plasma-based etch operation, and/or another suitable etch operation.

As shown in FIG. 3K, a supporting layer 150 may be formed in the recesses 320. The supporting layer 150 may include a conformal layer that conforms to the profile of the remaining area in the recesses 320. The supporting layer 150 may be formed on the top surfaces of the sacrificial plugs 324 in the recesses 320, and on the sidewalls of the recesses 320 (which correspond to the liner 152). Thus, the supporting layer 150 may be in contact with the top surfaces of the sacrificial plugs 324 in the recesses 320, and in contact with the portions of the liner 152 above the sacrificial plugs 324.

Without the sacrificial plugs 324, the supporting layer 150 would otherwise be formed on the bottom of the recesses 320. The sacrificial plugs 324 enable the supporting layer 150 to be formed higher up in the recesses 320 so that the sacrificial plugs 324 can be subsequently removed to form the air spacers 146.

In some implementations, a deposition tool may be used to deposit the supporting layer 150 using a conformal deposition technique such as ALD. In some implementations, a deposition tool may be used to deposit the supporting layer 150 using another deposition technique such as CVD and/or PVD, among other examples.

The supporting layer 150 may include a dielectric material. For example, the supporting layer 150 may include an oxide material such as a silicon oxide-based material. Examples of such materials include silicon dioxide (SiO₂), silicon oxycarbide (SiOC), silicon oxynitride (SiON), and/or silicon oxycarbonitride (SiOCN), among other examples.

As further shown in FIG. 3K, a sacrificial plug 324 may have a dimension D6 that corresponds to the height or vertical (z-direction) thickness of the sacrificial plug 324. The height or vertical (z-direction) thickness of the sacrificial plug 324 may be less than the height of the recess 320 to the top of the metal layer 140 to provide room for dielectric plugs that are to be formed in the remaining area in the recess 320. The greater the height or vertical (z-direction) thickness of the sacrificial plug 324 (dimension D6), the more room that is provided for the air spacers 146 of the isolation regions 142, which enables a lower dielectric constant to be achieved for the isolation regions 142 for reduced parasitic capacitance.

However, the greater the height or vertical (z-direction) thickness of the sacrificial plug 324 (dimension D6), the higher up in the recess 320 the supporting layer 150 is located (indicated in FIG. 3K as dimension D7). The higher up in the recess 320 the supporting layer 150 is located, the wider the gap that the supporting layer 150 has to span across in the recess 320 because of the taper of the recess 320 results in the width of the recess 320 being greater at the top of the recess 320 than at the bottom of the recess 320. The wider the gap that the supporting layer 150 has to span across in the recess 320 the higher the likelihood that the supporting layer 150 may collapse under the weight of the dielectric plug that is to be formed on the supporting layer 150 in the recess 320.

In some implementations, a ratio of the height or vertical (z-direction) thickness of the sacrificial plug 324 to the remaining vertical (z-direction) area in the recess 320 may be included in a range of approximately 2:1 to approximately 10:1 to provide sufficient area for the air spacer 146 (e.g., so that a low dielectric constant can be achieved) while a sufficiently low likelihood of collapse of the supporting layer 150 may be achieved. However, other values and ranges are within the scope of the present disclosure.

As shown in FIG. 3L, the sacrificial plugs 324 may be removed from the recesses 320 after the supporting layer 150 is formed. Removal of the sacrificial plugs 324 results in formation of the air spacers 146 of the isolation regions 142 between the bottoms of the recesses 320 and the supporting layer 150.

To remove the sacrificial plugs 324, a high-temperature operation (referred to as a burn out operation) may be performed to dislodge the material of the sacrificial plugs 324. For example, the sacrificial plugs 324 may be heated to a temperature of approximately 400 degrees Celsius or greater to cause or induce thermal cracking in the sacrificial plugs 324. This breaks up the sacrificial plugs 324 and enables the material of the sacrificial plugs 324 to be removed from the recesses 320 through the supporting layer 150.

The material of the supporting layer 150 may have a greater density than the material of the sacrificial plugs 324. This enables the sacrificial plugs 324 to withstand the high-temperature operation. In some implementations, pores may form in the supporting layer 150, and the pores enable the sacrificial plugs 324 to be removed from the supporting layer 150. In particular, material of the sacrificial plugs 324 may be removed through the pores in the supporting layer 150.

As shown in FIG. 3M, a dielectric plug layer 326 is formed in the top portions of the recesses 320 on the supporting layer 150. This results in the recesses 320 being sealed at the top, which results in formation of the air spacers 146 of the isolation regions 142 between the metallization structures 144. The supporting layer 150 prevents, minimizes, and/or otherwise reduces material of the dielectric plug layer 326 that is deposited further down in (e.g., at the bottom of) the recesses 320.

A deposition tool may be used to deposit the dielectric plug layer 326 using a PVD technique, an ALD technique, a CVD technique, an oxidation technique, and/or another suitable deposition technique. The dielectric plug layer 326 may be deposited in one or more deposition operations.

As shown in FIG. 3N, a planarization tool may be used to perform a planarization operation (e.g., a CMP operation) to planarize the dielectric plug layer 326 to remove excess material from the dielectric plug layer 326. The patterning layers 314-318 of the patterning stack 312 may also be removed in the planarization operation. Removal of the excess material of the dielectric plug layer 326 results in formation of the dielectric plugs 148 above the air spacers 146 of the isolation regions 142.

In some implementations, the remaining vertical (z-direction) area (indicated in FIG. 3N as a dimension D8) in an air spacer 146 may be included in a range of approximately 10 nanometers to approximately 20 nanometers. However, other values and ranges are within the scope of the present disclosure. In some implementations, the vertical (z-direction) thickness (indicated in FIG. 3N as a dimension D9) of a dielectric plug 148 may be included in a range of approximately 5 nanometers to approximately 20 nanometers. However, other values and ranges are within the scope of the present disclosure. In some implementations, a ratio of the remaining vertical (z-direction) area in an air spacer 146 to a vertical (z-direction) thickness of a dielectric plug 148 may be included in a range of approximately 2:1 to approximately 10:1. However, other values and ranges are within the scope of the present disclosure.

As shown in FIG. 3O, additional layers 130b-130e and 132b-132e of the interconnect layer 104 may be formed above the layer 132a. The layers 130b-130e and 132b-132e may be formed using copper interconnect formation techniques. For example, one or more deposition tools may be used to deposit alternating layers of ILD layers 126 and ESLs 128 in the interconnect layer 104 for the layers 130b-130e and 132b-132e. As another example, a deposition tool, an exposure tool, a developer tool, an etch tool, a planarization tool, a plating tool, and/or another semiconductor processing tool may be used to perform various operations to form the interconnect structures 154 of the layers 130b-130e, and/or to form the metallization structures 156 of the layers 132b-132e.

The ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

In some implementations, the interconnect layer 104 may be formed in a plurality of layers. For example, an ILD layer 126 and an ESL 128 of the layer 130b (e.g., the V1 layer) and/or of the layer 132b (e.g., the M1 layer) may be formed (e.g., using one or more deposition tools and/or one or more planarization tools), recesses may be formed in and/or through the ILD layer 126 and the ESL 128 (e.g., using an exposure tool, a developer tool, and/or an etch tool), and the interconnect structures 154 of the layer 130b and/or the metallization structures 156 of the layer 132b may be formed in the ILD layer 126 and the ESL 128 (e.g., using one or more deposition tools and/or one or more planarization tools). This process may be referred to as a dual damascene process. Alternatively, single damascene processes may be performed to form the interconnect structures 154 of the layer 130b and the metallization structures 156 of the layer 132b.

Another ILD layer 126 and another ESL 128 of the layer 130c (e.g., the V2 layer) and/or of the layer 132c (e.g., the M2 layer) may be formed (e.g., using one or more deposition tools and/or one or more planarization tools), recesses may be formed in and/or through the ILD layer 126 and the ESL 128 (e.g., using an exposure tool, a developer tool, and/or an etch tool), and the interconnect structures 154 of the layer 130c and/or the metallization structures 156 of the layer 132c may be formed in the ILD layer 126 and the ESL 128 (e.g., using one or more deposition tools and/or one or more planarization tools).

One or more deposition tools may be used to deposit the interconnect structures 154 and/or the metallization structures 156 using a PVD technique, an ALD technique, a CVD technique, an electroplating technique (e.g., an electro-chemical plating technique), and/or another suitable deposition technique. In some implementations, a planarization tool may be used to planarize the interconnect structures 154 and/or the metallization structures 156 after the interconnect structures 154 and/or the metallization structures 156 are deposited.

Additional layers of the interconnect layer 104 may be formed in a similar manner.

As indicated above, FIGS. 3A-3O is provided as an example. Other examples may differ from what is described with regard to FIGS. 3A-3O.

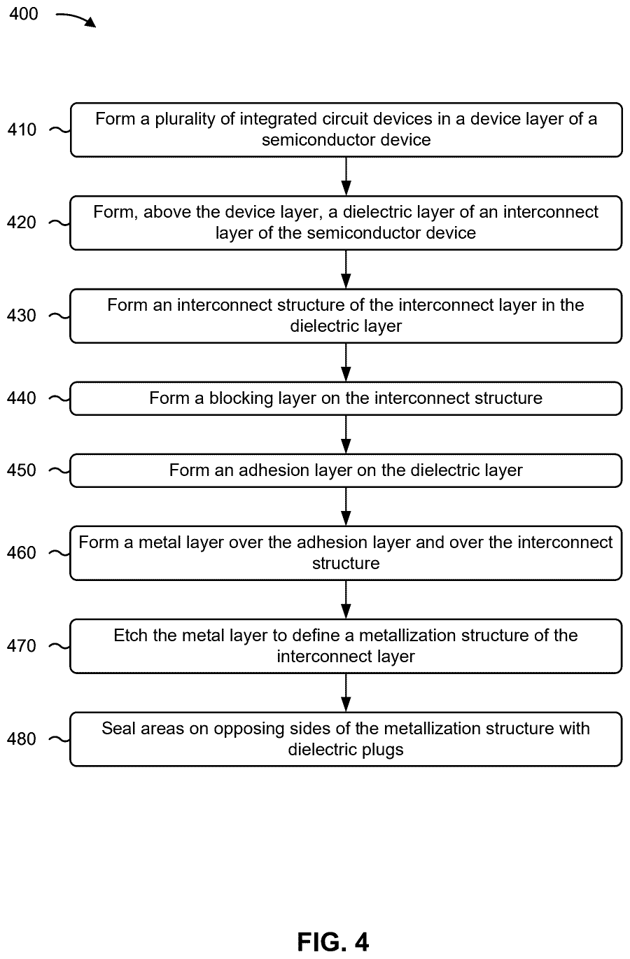

FIG. 4 is a flowchart of an example process 400 associated with forming a semiconductor device described herein. In some implementations, one or more process blocks of FIG. 4 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4, process 400 may include forming a plurality of integrated circuit devices in a device layer of a semiconductor device (block 410). For example, one or more semiconductor processing tools may be used to form a plurality of integrated circuit devices (e.g., integrated circuit devices 110) in a device layer (e.g., a device layer 102) of a semiconductor device (e.g., a semiconductor device 100), as described herein.

As further shown in FIG. 4, process 400 may include forming, above the device layer, a dielectric layer of an interconnect layer of the semiconductor device (block 420). For example, one or more semiconductor processing tools may be used to form, above the device layer, a dielectric layer (e.g., an ILD layer 126, an ESL 128) of an interconnect layer (e.g., an interconnect layer 104) of the semiconductor device, as described herein.

As further shown in FIG. 4, process 400 may include forming an interconnect structure of the interconnect layer in the dielectric layer (block 430). For example, one or more semiconductor processing tools may be used to form an interconnect structure (e.g., a source/drain interconnect structure 134, a gate interconnect structure 136) of the interconnect layer in the dielectric layer, as described herein. In some implementations, the interconnect structure is coupled to at least one of the integrated circuit devices.

As further shown in FIG. 4, process 400 may include forming a blocking layer on the interconnect structure (block 440). For example, one or more semiconductor processing tools may be used to form a blocking layer (e.g., a blocking layer 302) on the interconnect structure, as described herein.

As further shown in FIG. 4, process 400 may include forming an adhesion layer on the dielectric layer (block 450). For example, one or more semiconductor processing tools may be used to form an adhesion layer (e.g., an adhesion layer 138) on the dielectric layer, as described herein.

As further shown in FIG. 4, process 400 may include forming a metal layer over the adhesion layer and over the interconnect structure (block 460). For example, one or more semiconductor processing tools may be used to form a metal layer (e.g., a metal layer 140) over the adhesion layer and over the interconnect structure, as described herein.

As further shown in FIG. 4, process 400 may include etching the metal layer to define a metallization structure of the interconnect layer (block 470). For example, one or more semiconductor processing tools may be used to etch the metal layer to define a metallization structure (e.g., a metallization structure 144) of the interconnect layer, as described herein. In some implementations, the metallization structure located over and electrically coupled to the interconnect structure.

As further shown in FIG. 4, process 400 may include sealing areas on opposing sides of the metallization structure with dielectric plugs (block 480). For example, one or more semiconductor processing tools may be used to seal areas on opposing sides of the metallization structure with dielectric plugs (e.g., dielectric plugs 148), as described herein.

Process 400 may include additional implementations, such as any single implementation or any combination of implementations described below and/or in connection with one or more other processes described elsewhere herein.

In a first implementation, the blocking layer inhibits formation of the adhesion layer on the interconnect structure.

In a second implementation, alone or in combination with the first implementation, forming the adhesion layer includes depositing a layer of titanium nitride (TiN) by ALD.

In a third implementation, alone or in combination with one or more of the first and second implementations, process 400 includes removing the blocking layer from the interconnect structure after forming the adhesion layer.

In a fourth implementation, alone or in combination with one or more of the first through third implementations, removing the blocking layer includes performing a plasma treatment operation using an inert-gas-based plasma to remove the blocking layer.

In a fifth implementation, alone or in combination with one or more of the first through fourth implementations, forming the metal layer includes forming the metal layer after removing the blocking layer.

In a sixth implementation, alone or in combination with one or more of the first through fifth implementations, forming the metal layer includes forming a portion (e.g., a portion 310) of the metal layer directly on the interconnect structure such that the portion of the metal layer extends through the adhesion layer.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

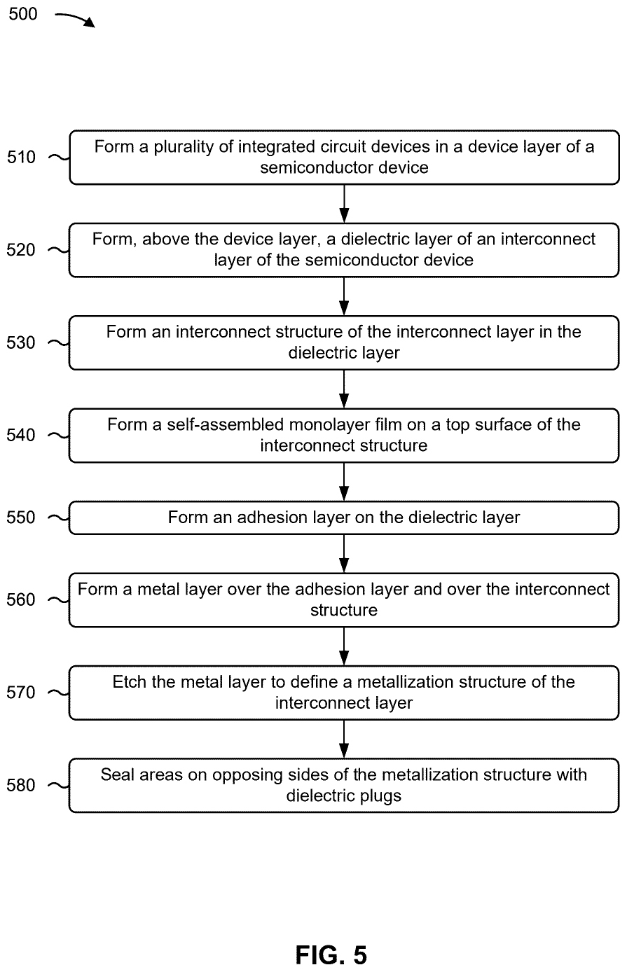

FIG. 5 is a flowchart of an example process 500 associated with forming a semiconductor device described herein. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include forming a plurality of integrated circuit devices in a device layer of a semiconductor device (block 510). For example, one or more semiconductor processing tools may be used to form a plurality of integrated circuit devices (e.g., integrated circuit devices 110) in a device layer (e.g., a device layer 102) of a semiconductor device (e.g., a semiconductor device 100), as described herein.

As further shown in FIG. 5, process 500 may include forming, above the device layer, a dielectric layer of an interconnect layer of the semiconductor device (block 520). For example, one or more semiconductor processing tools may be used to form, above the device layer, a dielectric layer (e.g., an ILD layer 126, an ESL 128) of an interconnect layer (e.g., an interconnect layer 104) of the semiconductor device, as described herein.

As further shown in FIG. 5, process 500 may include forming an interconnect structure of the interconnect layer in the dielectric layer (block 530). For example, one or more semiconductor processing tools may be used to form an interconnect structure of the interconnect layer in the dielectric layer, as described herein. In some implementations, the interconnect structure includes a source/drain interconnect structure 134 or a gate interconnect structure 136, and is coupled to at least one of the integrated circuit devices.

As further shown in FIG. 5, process 500 may include forming a self-assembled monolayer film on a top surface of the interconnect structure (block 540). For example, one or more semiconductor processing tools may be used to form a self-assembled monolayer film (e.g., a blocking layer 302) on a top surface of the interconnect structure, as described herein.

As further shown in FIG. 5, process 500 may include forming an adhesion layer on the dielectric layer (block 550). For example, one or more semiconductor processing tools may be used to form an adhesion layer (e.g., an adhesion layer 138) on the dielectric layer, as described herein. In some implementations, the self-assembled monolayer film inhibits adsorption of material of the adhesion layer onto the top surface of the interconnect structure.

As further shown in FIG. 5, process 500 may include forming a metal layer over the adhesion layer and over the interconnect structure (block 560). For example, one or more semiconductor processing tools may be used to form a metal layer (e.g., a metal layer 140) over the adhesion layer and over the interconnect structure, as described herein.

As further shown in FIG. 5, process 500 may include etching the metal layer to define a metallization structure of the interconnect layer (block 570). For example, one or more semiconductor processing tools may be used to etch the metal layer to define a metallization structure (e.g., a metallization structure 144) of the interconnect layer, as described herein. In some implementations, the metallization structure located over and electrically coupled to the interconnect structure.

As further shown in FIG. 5, process 500 may include sealing areas on opposing sides of the metallization structure with dielectric plugs (block 580). For example, one or more semiconductor processing tools may be used to seal areas on opposing sides of the metallization structure with dielectric plugs (e.g., dielectric plugs 148), as described herein.

Process 500 may include additional implementations, such as any single implementation or any combination of implementations described below and/or in connection with one or more other processes described elsewhere herein.

In a first implementation, the self-assembled monolayer film contains a material that includes an anchor group (e.g., an anchor group 304) and a side chain group (e.g., a side chain group 306).

In a second implementation, alone or in combination with the first implementation, the anchor group inhibits adsorption of the material of the self-assembled monolayer film onto the dielectric layer, and the anchor group promotes adsorption of the material of the self-assembled monolayer film onto the interconnect structure.

In a third implementation, alone or in combination with one or more of the first and second implementations, the anchor group includes at least one of a carbonyl group, a nitrile group, or an amide group.

In a fourth implementation, alone or in combination with one or more of the first through third implementations, the side chain group includes at least one of an alkyl group, or an aryl group.

In a fifth implementation, alone or in combination with one or more of the first through fourth implementations, forming the self-assembled monolayer film includes dispensing, onto the semiconductor device, a solution that contains material of the self-assembled monolayer film dissolved in a solvent, and performing a curing operation to evaporate the solvent.

In a sixth implementation, alone or in combination with one or more of the first through fifth implementations, the curing operation includes a spin dry operation.

In a seventh implementation, alone or in combination with one or more of the first through sixth implementations, the solvent includes at least one of a gamma-butyrolactone (GBL) solvent, a diethylformamide (DEF) solvent, a propylene glycol methyl ether acetate (PGMEA) solvent, or a propylene glycol methyl ether (PGME) solvent.

In an eighth implementation, alone or in combination with one or more of the first through seventh implementations, forming the adhesion layer includes depositing a layer of titanium nitride (TiN) by ALD.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a layer of conductive material is formed above a bottom-most layer of interconnect structures in an interconnect layer of a semiconductor device, and the layer of conductive material is etched to define the bottom-most layer of metallization structures from the layer of conductive material. To reduce contact resistance between the bottom-most layer of interconnect structures and the bottom-most layer of metallization structures in the interconnect layer, an adhesion layer may be formed in a selective manner so that the adhesion layer is formed only on an underlying dielectric layer and not on the bottom-most layer of interconnect structures. Selective deposition of the adhesion layer may be achieved using a blocking layer that is selectively formed on the bottom-most layer of interconnect structures. The blocking layer may include a self-assembled monolayer that selectively grows on the bottom-most layer of interconnect structures and not on the underlying dielectric layer in which the bottom-most layer of interconnect structures were formed. The selective growth of the self-assembled monolayer on the bottom-most layer of interconnect structures and not on the underlying dielectric layer inhibits deposition of the adhesion layer on the bottom-most layer of interconnect structures while still enabling the adhesion layer to be deposited on the underlying dielectric layer. In this way, the self-assembled monolayer enables a low contact resistance to be achieved, with minimal impact to the structural integrity of the bottom-most layer of metallization structures.

As described in greater detail above, some implementations described herein provide a method. The method includes forming a plurality of integrated circuit devices in a device layer of a semiconductor device. The method includes forming, above the device layer, a dielectric layer of an interconnect layer of the semiconductor device. The method includes forming an interconnect structure of the interconnect layer in the dielectric layer, where the interconnect structure is coupled to at least one of the integrated circuit devices. The method includes forming a blocking layer on the interconnect structure. The method includes forming an adhesion layer on the dielectric layer. The method includes forming a metal layer over the adhesion layer and over the interconnect structure. The method includes etching the metal layer to define a metallization structure of the interconnect layer, where the metallization structure located over and electrically coupled to the interconnect structure. The method includes sealing areas on opposing sides of the metallization structure with dielectric plugs.

As described in greater detail above, some implementations described herein provide a method. The method includes forming a plurality of integrated circuit devices in a device layer of a semiconductor device. The method includes forming, above the device layer, a dielectric layer of an interconnect layer of the semiconductor device. The method includes forming an interconnect structure of the interconnect layer in the dielectric layer, where the interconnect structure includes a source/drain interconnect structure or a gate interconnect structure, and is coupled to at least one of the integrated circuit devices. The method includes forming a self-assembled monolayer film on a top surface of the interconnect structure. The method includes forming an adhesion layer on the dielectric layer, where the self-assembled monolayer film inhibits adsorption of material of the adhesion layer onto the top surface of the interconnect structure. The method includes forming a metal layer over the adhesion layer and over the interconnect structure. The method includes etching the metal layer to define a metallization structure of the interconnect layer, where the metallization structure located over and electrically coupled to the interconnect structure. The method includes sealing areas on opposing sides of the metallization structure with dielectric plugs.

As described in greater detail above, some implementations described herein provide a semiconductor device. The semiconductor device includes a device layer. The semiconductor device includes an integrated circuit device in the device layer. The semiconductor device includes a dielectric layer above the device layer. The semiconductor device includes an interconnect structure in the dielectric layer and electrically coupled to a contact of the integrated circuit device. The semiconductor device includes an adhesion layer above the dielectric layer, where the adhesion layer contains an adhesion material. The semiconductor device includes a metal layer above the adhesion layer. The semiconductor device includes a metallization structure above and electrically coupled to the interconnect structure, where the metallization structure is laterally adjacent to the metal layer, and where an interface between the metallization structure and the interconnect structure is free of the adhesion material of the adhesion layer. The semiconductor device includes an isolation region along at least one sidewall of the metallization structure, where the isolation region includes an air spacer along a first portion of the sidewall and a dielectric plug along a second portion of the sidewall above the first portion.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of integrated circuit devices in a device layer of a semiconductor device;
forming, above the device layer, a dielectric layer of an interconnect layer of the semiconductor device;
forming an interconnect structure of the interconnect layer in the dielectric layer,
wherein the interconnect structure is coupled to at least one of the integrated circuit devices;
forming a blocking layer on the interconnect structure;
forming an adhesion layer on the dielectric layer;
forming a metal layer over the adhesion layer and over the interconnect structure;
etching the metal layer to define a metallization structure of the interconnect layer,
wherein the metallization structure located over and electrically coupled to the interconnect structure; and
sealing areas on opposing sides of the metallization structure with dielectric plugs.

2. The method of claim 1, wherein the blocking layer inhibits formation of the adhesion layer on the interconnect structure.

3. The method of claim 1, wherein forming the adhesion layer comprises:
depositing a layer of titanium nitride (TiN) by atomic layer deposition (ALD).

4. The method of claim 1, further comprising:
removing the blocking layer from the interconnect structure after forming the adhesion layer.

5. The method of claim 4, wherein removing the blocking layer comprises:
performing a plasma treatment operation using an inert-gas-based plasma to remove the blocking layer.

6. The method of claim 4, wherein forming the metal layer comprises:
forming the metal layer after removing the blocking layer.

7. The method of claim 6, wherein forming the metal layer comprises:
forming a portion of the metal layer directly on the interconnect structure such that the portion of the metal layer extends through the adhesion layer.

8. A method, comprising:
forming a plurality of integrated circuit devices in a device layer of a semiconductor device;
forming, above the device layer, a dielectric layer of an interconnect layer of the semiconductor device;
forming an interconnect structure of the interconnect layer in the dielectric layer,
wherein the interconnect structure comprises a source/drain interconnect structure or a gate interconnect structure, and is coupled to at least one of the integrated circuit devices;
forming a self-assembled monolayer film on a top surface of the interconnect structure;
forming an adhesion layer on the dielectric layer,
wherein the self-assembled monolayer film inhibits adsorption of material of the adhesion layer onto the top surface of the interconnect structure;
forming a metal layer over the adhesion layer and over the interconnect structure;
etching the metal layer to define a metallization structure of the interconnect layer,
wherein the metallization structure located over and electrically coupled to the interconnect structure; and
sealing areas on opposing sides of the metallization structure with dielectric plugs.

9. The method of claim 8, wherein the self-assembled monolayer film contains a material that comprises an anchor group and a side chain group.

10. The method of claim 9, wherein the anchor group inhibits adsorption of the material of the self-assembled monolayer film onto the dielectric layer; and
wherein the anchor group promotes adsorption of the material of the self-assembled monolayer film onto the interconnect structure.

11. The method of claim 9, wherein the anchor group comprises at least one of:
a carbonyl group,
a nitrile group, or
an amide group.

12. The method of claim 8, wherein the side chain group comprises at least one of:
an alkyl group, or
an aryl group.

13. The method of claim 8, wherein forming the self-assembled monolayer film comprises:
dispensing, onto the semiconductor device, a solution that contains material of the self-assembled monolayer film dissolved in a solvent; and
performing a curing operation to evaporate the solvent.

14. The method of claim 13, wherein the curing operation comprises a spin dry operation.

15. The method of claim 13, wherein the solvent comprises at least one of:
a gamma-butyrolactone (GBL) solvent,
a diethylformamide (DEF) solvent,
a propylene glycol methyl ether acetate (PGMEA) solvent, or
a propylene glycol methyl ether (PGME) solvent.

16. The method of claim 8, wherein forming the adhesion layer comprises:
depositing a layer of titanium nitride (TiN) by atomic layer deposition (ALD).

17. A semiconductor device, comprising:
a device layer;
an integrated circuit device in the device layer;
a dielectric layer above the device layer;
an interconnect structure in the dielectric layer and electrically coupled to a contact of the integrated circuit device;
an adhesion layer above the dielectric layer,
wherein the adhesion layer contains an adhesion material;
a metal layer above the adhesion layer; and
a metallization structure above and electrically coupled to the interconnect structure,
wherein the metallization structure is laterally adjacent to the metal layer, and
wherein an interface between the metallization structure and the interconnect structure is free of the adhesion material of the adhesion layer; and
an isolation region along at least one sidewall of the metallization structure,
wherein the isolation region comprises:
an air spacer along a first portion of the sidewall; and
a dielectric plug along a second portion of the sidewall above the first portion.

18. The semiconductor device of claim 17, wherein a bottom surface of the metallization structure is lower in the semiconductor device than a top surface of the adhesion layer.

19. The semiconductor device of claim 17, wherein a bottom surface of the metallization structure is approximately co-planar with a bottom surface of the adhesion layer.

20. The semiconductor device of claim 17, wherein the adhesion material of the adhesion layer has an amorphous structure.
